(19) United States
(12) Patent Application Publication
(10) Pub. No.: US 2010/0194409 A1
(43) Pub. Date: Aug. 5, 2010

(54) METHOD OF ELECTRICALLY DETECTING A BIOLOGICAL ANALYTE MOLECULE

(75) Inventors: Zhiqiang Gao, Singapore (SG); Yi Fan, Singapore (SG); Xiantong Chen, Singapore (SG); Jinming Kong, Singapore (SG)

Correspondence Address: INTELLECTUAL PROPERTY / TECHNOLOGY LAW, PO BOX 14329, RESEARCH TRIANGLE PARK, NC, 27709, US

(73) Assignee: AGENCY FOR SCIENCE, TECHNOLOGY AND RESEARCH, (SG)

(21) Appl. No.: 12/377,404

(22) PCT Filed: Aug. 14, 2007
(86) PCT No.: PCT/SG2007/000251

§ 371 Date: Feb. 13, 2009

Related U.S. Application Data
(60) Provisional application No. 60/838,036, filed on Aug. 16, 2006.

(51) Int. Cl. G01R 27/08; C01B 31/00

(52) U.S. Cl. 324/693; 423/445 R

(57) ABSTRACT

The invention provides a method of electrically detecting a biological analyte molecule by means of a pair of electrodes. The electrodes are arranged at a distance from one another within a sensing zone. A capture molecule, which has an affinity to the analyte molecule and which is capable of forming a complex with the analyte molecule, is immobilised on an immobilisation unit. The immobilisation unit is contacted with a solution suspected to comprise the analyte molecule. The analyte molecule is allowed to form a complex with the capture molecule. The invention also provides a probe defined by a nanoparticulate tag that comprises or consists of electrically conducting matter that is capable of chemically interacting with the analyte molecule. In the method of the invention the electrically conducting nanoparticulate tag is added. Thereby the electrically conducting nanoparticulate tag is allowed to associate to the complex formed between the capture molecule and the analyte molecule. The presence of the analyte molecule is determined based on an electrical characteristic, influenced by the electrically conducting nanoparticulate tag, of a region in the sensing zone.

### CROSS-REFERENCE TO RELATED APPLICATIONS

This application claims the benefit of priority of U.S. patent application 60/838,036 “Detection of Nucleic Acids by Directly Labeling Phosphates with Conductive Nanoparticles” filed on Aug. 16, 2006, the content of which is incorporated herein by reference for all purposes, including an incorporation of any element or part of the description, claims or drawings not contained herein and referred to in Rule 20.5(a) of the PCT, pursuant to Rule 4.18 of the PCT.

### FIELD OF THE INVENTION

The present invention relates to a method of electrically detecting a biological analyte molecule, in particular detecting the analyte molecule by means of an electrode pair.

### BACKGROUND OF THE INVENTION

The detection and quantification of biological molecules is a fundamental method not only in analytical chemistry but also in biochemistry, food technology and medicine. Methods of electrical detection and/or quantification, which have become attractive owing to their simplicity, low cost, and excellent portability, typically rely on an arrangement termed a biosensor, the prototype of which was presented in 1962. A biosensor includes an immobilised capture probe that is able to selectively recognize the analyte and a suitable transducer that is able to relay the signal for further analysis. Electrical and electrochemical biosensors allow for fast and real-time analysis. Electrical techniques include conductivity measurements, which can for instance be based on an oligonucleotide functionalised with a gold nanoparticle (Park, S. J., et al., Science (2002) 295, 1503-1506) or with a conductive polymer (US patent application 2005/0079533).

In many detection methods the binding of an analyte to the capture probe changes the conductivity or other electrical properties between two electrodes. In other biosensors a field effect transistor (FET), such as an ion-sensitive field effect transistor (ISFET) is used, for instance by modifying the gate electrode or by immobilising a capture probe thereon (see Schoning, M. J. & Poghossian, A., Analyst (2002) 127, 1137-1151 for a review). The capture probe is typically an immunoglobulin in cases where the analyte is a protein or an oligonucleotide capture probe in cases where the analyte is a nucleic acid. Mirkin and co-workers (Mirkin, C. A., et al., Nature (1996) 382, 607) used gold nanoparticles and oligonucleotides as analytes that bound to the probe component. Using this model they showed that the resulting assembly of the gold nanoparticles that were attached to the oligonucleotides lead to a detectable colour change. Respective nanoparticles have also been used for electrical detection (see Rosi, N. L., et al., Chem. Rev. (2005) 105, 1647-1562 for an overview). In the electrical detection scheme, capture probes are immobilised in micron-sized gaps between electrodes in a DNA array (Cai, H., et al., J. Electroanalyt. Chem. [2001] 510, 78-85). Hybridization with analyte DNA and Au nanoparticle-labeled detection probes localizes the nanoparticles in the gap, while subsequent silver deposition creates a ‘bridge’ across the gap. The detection of a conductivity change results in a detection limit of 500 fM (Cai et al., supra).

Unfortunately, the current amplification strategy for electrical signal generation often involves multiple steps of deposition and enhancement. It would therefore be desirable to have a reliable method that is both sensitive and relatively simple to be carried out. Thus, there remains a need for an alternative method for the detection of analyte molecules.

Accordingly it is an object of the present invention to provide a method of electrically detecting a biological analyte molecule, which avoids the discussed disadvantages.

### SUMMARY OF THE INVENTION

According to a first aspect, the invention provides a method for electrically detecting a biological analyte molecule by means of a pair of electrodes. The electrodes are arranged at a distance from one another. Further, the pair of electrodes is arranged within a sensing zone. The method includes immobilising on an immobilisation unit a capture molecule. The capture molecule has an affinity to the analyte molecule and is capable of forming a complex with the analyte molecule. The method further includes contacting the immobilisation unit with a solution suspected to include the analyte molecule. The method also includes allowing the analyte molecule to form a complex with the capture molecule. Furthermore the method includes adding an electrically conducting nanoparticulate tag. The electrically conducting nanoparticulate tag includes or consists of electrically conducting matter that is capable of chemically interacting with the analyte molecule. Thereby the method includes thereby allowing the electrically conducting nanoparticulate tag to associate to the complex formed between the capture molecule and the analyte molecule. Further, the method includes determining the presence of the analyte molecule based on an electrical characteristic of a region in the sensing zone. The electrical characteristic is influenced by the electrically conducting nanoparticulate tag.

According to a particular embodiment, adding the nanoparticulate tag includes adding a plurality of electrically conducting nanoparticles. Thereby the method includes allowing the plurality of electrically conducting nanoparticles to associate to the complex formed between the capture molecule and the analyte molecule. As a result an electrically conducting network of the electrically conducting nanoparticles is formed. The network is associated with the complex formed between the capture molecule and the analyte molecule.

According to a further aspect, the invention provides a probe. The probe is defined by an electrically conducting nanoparticulate tag. The electrically conducting nanoparticulate tag includes or consists of matter that has an affinity to a biological analyte molecule and is capable of forming a complex with the analyte molecule. The matter is a metal, a metalloid, carbon or a polymer.

According to yet a further aspect the invention provides a kit for electrically detecting a biological analyte molecule. The kit includes a pair of electrodes. The electrodes are arranged at a distance from one another. Further, the pair of electrodes is arranged within a sensing zone. The kit also includes an immobilisation unit. The immobilisation unit is arranged within the sensing zone. The kit further includes a capture molecule. The capture molecule has an affinity to the analyte molecule and is capable of forming a complex with the analyte molecule. The kit also includes an electrically conducting nanoparticulate tag. The electrically conducting nanoparticulate tag includes or consists of electrically conducting matter that is capable of chemically interacting with the analyte molecule.

### BRIEF DESCRIPTION OF THE DRAWINGS

The invention will be better understood with reference to the detailed description when considered in conjunction with the non-limiting examples and the accompanying drawings.

FIG. 1 depicts a schematic representation of a biosensor according to the invention with an immobilised capture molecule (1) (A), forming a complex with the analyte molecule (10) (B, C), to which an electrically conducting nanoparticulate tag (14) associates (D, E).

FIG. 2 depicts a schematic representation of three further biosensors according to the invention, in which the capture molecule is immobilised on the gate electrode (4) of a field effect transistor (FIG. 2A), on a sensing unit of an extended gate field effect transistor (FIG. 2B), and on an additional, electrically floating gate (9) of a field effect transistor (FIG. 2C).

FIG. 3 depicts a TEM micrograph of electroconductive nanoparticles, which are activated indium tin oxide (ITO) nanoparticles.

FIG. 4 shows the dependence of conductance of the biosensor () and the control biosensor (∘) on incubation time in 10 mg/ml indium tin oxide nanoparticle in pH 4.0 0.10 M NaNO₃. Hybridization conditions: 60 min at 50° C. in 1.0 nM nucleic acid in a buffer of 10 mM Tris-HCl, pH 8.5, 1.0 mM EDTA and 0.10 M NaCl. For clarity purposes, the conductance of the control biosensor was scaled up 1000 fold.

FIG. 5 shows the effect of the composition of the incubation buffer on the response of the biosensor. pH 4.0 0.10 M NaNO₃ () and pH 4.0 0.10 M phosphate (∘). Other conditions are as for FIG. 4.

FIG. 6 depicts a calibration curve for a nucleic acid. Conditions are as for FIG. 4.

### DETAILED DESCRIPTION OF THE INVENTION

The present invention provides a method of the electrically detecting a biological analyte molecule. As used herein, the term ‘detection’, ‘detecting’ or ‘detect’ refers broadly to measurements which provide an indication of the presence or absence, either qualitatively or quantitatively, of an analyte. Accordingly, the term encompasses quantitative measurements of the concentration of an analyte nucleic acid molecule in a sample, as well as qualitative measurements in which for instance different types of analyte molecules in a given sample are identified, or, as a further example, the behaviour of a particular analyte molecule in a given environment is observed. The term ‘quantification’ refers solely to quantitative measurements of the amount, e.g. the concentration, of an analyte molecule. Any biological analyte molecule may be detected using the method of the present invention. Typically, a respective analyte molecule is, originates from or is present in biological material. Examples of suitable biological material include, but are not limited to, a nucleotide, a polynucleotide, a nucleic acid molecule, an amino acid, a peptide, a polypeptide, a protein, a biochemical composition, a lipid, a carbohydrate, a cell, a microorganisms and any combinations thereof. The biological analyte molecule may for example be, be defined by, or include a nucleic acid molecule, an oligonucleotide, a protein, an oligopeptide, a polysaccharide and an oligosaccharide.

The term “nucleic acid molecule” as used herein refers to any nucleic acid in any possible configuration, such as single stranded, double stranded or a combination thereof. Nucleic acids include for instance DNA molecules, RNA molecules, analogues of the DNA or RNA generated using nucleotide analogues or using nucleic acid chemistry, locked nucleic acid molecules (LNA), and protein nucleic acids molecules (PNA). LNA has a modified RNA backbone with a methylene bridge between C4′ and O2′, providing the respective molecule with a higher duplex stability and nuclease resistance. DNA or RNA may be of genomic or synthetic origin. A respective nucleic acid may furthermore contain non-natural nucleotide analogues and/or be linked to an affinity tag or a label.

Many nucleotide analogues are known and can be used in nucleic acids used in the methods of the invention. A nucleotide analogue is a nucleotide containing a modification at for instance the base, sugar, or phosphate moieties. As an illustrative example, a substitution of 2′-OH residues of siRNA with 2′F, 2′O-Me or 2′H residues is known to improve the in vivo stability of the respective RNA. Modifications at the base moiety include natural and synthetic modifications of A, C, G, and T/U, different purine or pyrimidine bases, such as uracil-5-yl, hypoxanthin-9-yl, and 2-aminoadenin-9-yl, as well as non-purine or non-pyrimidine nucleotide bases. Other nucleotide analogues serve as universal bases. Universal bases include 3-nitropyrrole and 5-nitroindole. Universal bases are able to form a base pair with any other base. Base modifications often can be combined with for example a sugar modification, such as for instance 2′-O-methoxyethyl, e.g. to achieve unique properties such as increased duplex stability.

A biological analyte molecule that can be detected (including quantified) by the method of the present invention can originate from a large variety of sources. Samples that include or are suspected or expected to include the respective analyte molecule include biological samples derived from plant material and animal tissue (e.g. insects, fish, birds, cats, livestock, domesticated animals and human beings), as well as blood, urine, sperm, stool samples obtained from such animals. Biological tissue of not only living animals, but also of animal carcasses or human cadavers can be analysed, for example, to carry out post mortem tissue biopsy or for identification purposes, for instance. In other embodiments, samples may be water that is obtained from non-living sources such as from the sea, lakes, reservoirs, or industrial water to determine the presence of a targeted bacteria, pollutant, element or compound. Further embodiments include, but are not limited to, dissolved liquids or suspensions of solids. In yet another embodiment, quantitative data relating to the analyte is used to determine a property of the fluid sample, including analyte concentration in the fluid sample, reaction kinetic constants, analyte purity and analyte heterogeneity.

Accordingly, any of the following samples selected from, but not limited to, the group consisting of a soil sample, an air sample, an environmental sample, a cell culture sample, a bone marrow sample, a rainfall sample, a fallout sample, a sewage sample, a ground water sample, an abrasion sample, an archaeological sample, a food sample, a blood sample, a serum sample, a plasma sample, an urine sample, a stool sample, a semen sample, a lymphatic fluid sample, a cerebrospinal fluid sample, a nasopharyngeal wash sample, a sputum sample, a mouth swab sample, a throat swab sample, a nasal swab sample, a bronchoalveolar lavage sample, a bronchial secretion sample, a milk sample, an amniotic fluid sample, a biopsy sample, a cancer sample, a tumour sample, a tissue sample, a cell sample, a cell culture sample, a cell lysate sample, a virus culture sample, a nail sample, a hair sample, a skin sample, a forensic sample, an infection sample, a nosocomial infection sample, a production sample, a drug preparation sample, a biological molecule production sample, a protein preparation sample, a lipid preparation sample, a carbohydrate preparation sample, a space sample, an extraterrestrial sample or any combination thereof may be processed in a method of the invention. Where desired, a respective sample may have been pre-processed to any degree. As an illustrative example, a tissue sample may have been digested, homogenised or centrifuged prior to being used with the device of the present invention. The sample may furthermore have been prepared in form of a fluid, such as a solution. Examples include, but are not limited to, a solution or a slurry of a nucleotide, a polynucleotide, a nucleic acid, a peptide, a polypeptide, an amino acid, a protein, a synthetic polymer, a biochemical composition, an organic chemical composition, an inorganic chemical composition, a metal, a lipid, a carbohydrate or of any combinations thereof. Further examples include, but are not limited to, a suspension of a cell, a virus, a microorganism, a pathogen or of any combinations thereof. It is understood that a sample may furthermore include any combination of the aforementioned examples. As an illustrative example, the sample that includes the biological analyte molecule (e.g. nucleic acid molecule) may be a mammal sample, for example a human or mouse sample, such as a sample of total mRNA. The analyte, which may be suspected or known to be present within the sample, may also be termed the “target”, and accordingly an analyte molecule may be termed the “target molecule”.

In some embodiments the sample is a fluid sample, such as a liquid. In other embodiments the sample is solid. In case of a solid or gaseous sample, an extraction by standard techniques known in the art may be carried out in order to dissolve the biological analyte molecule in a solvent. Accordingly, the biological analyte molecule, or the suspected/expected biological analyte molecule, is provided in form of a solution for the use in the present invention. As an illustrative example, the biological analyte molecule may be provided in form of an aqueous solution.

If desired, further matter may be added to the respective solution, for example dissolved or suspended therein. As an illustrative example an aqueous solution may include one or more buffer compounds. Numerous buffer compounds are used in the art and may be used to carry out the various processes described herein. Examples of buffers include, but are not limited to, solutions of salts of phosphate, carbonate, succinate, carbonate, citrate, acetate, formate, barbiturate, oxalate, lactate, phthalate, maleate, cacodylate, borate, N-(2-acetamido)-2-amino-ethanesulfonate (also called (ACES), N-(2-hydroxyethyl)-piperazine-N′-2-ethanesulfonic acid (also called HEPES), 4-(2-hydroxyethyl)-1-piperazine-propanesulfonic acid (also called HEPPS), piperazine-1,4-bis(2-ethanesulfonic acid) (also called PIPES), (2-[Tris(hydroxymethyl)-methylamino]-1-ethansulfonic acid (also called TES), 2-cyclohexylamino-ethansulfonic acid (also called CHES) and N-(2-acetamido)-iminodiacetate (also called ADA). Any counter ion may be used in these salts; ammonium, sodium, and potassium may serve as illustrative examples. Further examples of buffers include, but are not limited to, triethanolamine, diethanolamine, ethylamine, triethylamine, glycine, glycylglycine, histidine, tris(hydroxymethyl)aminomethane (also called TRIS), bis-(2-hydroxyethyl)-imino-tris(hydroxymethyl)methane (also called BIS-TRIS), and N-[-Tris(hydroxymethyl)-methyl]-glycine (also called TRICINE), to name a few. The buffers may be aqueous solutions of such buffer compounds or solutions in a suitable polar organic solvent. One or more respective solutions may be used to accommodate the suspected biological analyte molecule as well as other matter used, throughout an entire method of the present invention.

Further examples of matter that may be added, include salts, detergents or chelating compounds. As yet a further illustrative example, nuclease inhibitors may need to be added in order to maintain a nucleic acid molecule in an intact state. While it is understood that for the purpose of detection any matter added should not obviate the formation of a complex between the capture molecule (such as a nucleic acid capture molecule including a PNA capture molecule, see below) and the biological analyte molecule, for the purpose of carrying out a control measurement a respective agent may be used that blocks said complex formation.

As an illustrative example, a bacteria, virus, or DNA sequence can be detected using the present invention for identifying a disease state. A respective bacterium of virus may for example be identified by one or more marker proteins specific for the respective bacterium of virus. Diseases which can be detected include communicable diseases such as Severe Acute Respiratory Syndrome (SARS), Hepatitis A, B and C, HIV/AIDS, malaria, polio and tuberculosis; congenital conditions that can be detected pre-natally (e.g. via the detection of chromosomal abnormalities) such as sickle cell anemia, heart malformations such as atrial septal defect, supravalvular aortic stenosis, cardiomyopathy, Down's syndrome, clubfoot, polydactyl), syndactyl), atropic fingers, lobster claw hands and feet, etc. The present method is also suitable for the detection and screening for cancer.

The method of the present invention allows detecting an analyte molecule by means of an electrode arrangement such as a pair of electrodes. The term “electrode” as used herein is employed in its conventional sense, thereby referring to an object that is capable of serving as an electric conductor, through which an electrical current or voltage may be brought into and/or out of a medium in contact with the electrode. Typically an electrode is one of at least two terminals of an electrically conducting medium. The term “electrode arrangement” or “pair of electrodes” as used herein refers to any number of electrodes of two or higher. Accordingly, two or more electrodes are provided in the method (as well as the kits, see below) of the invention. The electrodes are arranged at a distance from one another. In embodiments where two electrodes are provided, the two electrodes may for instance be separated by a gap. In such embodiments the two electrodes of this pair of electrodes may face each other across the gap. In some embodiments the two electrodes are at least essentially parallel. The electrodes may be of any desired dimension and shape. They may for example have the shape of a flat, arched, concave or convex slab. In some embodiments they may have the shape of a ring (for an example see Green, B. J, & Hudson, J. L., Phys. Rev. E (2001), 63, 026214). In some embodiments interdigital electrodes are provided, which typically include a digitlike or fingerlike pattern of parallel in-plane electrodes (see Mamishev, A. V., Proc. IEEE (2004), 92, 5, 808-845, or Matsue, T., Trends Anal. Chem. (1993), 12, 3, 100-108 for examples). In some embodiments an array of electrodes may be provided. If desired, one or more floating electrodes may be used. In some embodiments the electrodes that are provided are of similar size, for example of identical size.

The distance between the two or more electrodes (to which is also referred herein as gap) may be of any dimension, as long as the change of an electrical characteristic of the respective region can be determined in the method of the present invention (see below), so that a detection of an analyte molecule can be carried out. In some embodiments where more than two electrodes are provided, the distance at which the electrodes are arranged may be identical between each of the respective electrodes. In other such embodiments the distance at which the electrodes are arranged may be identical between some of the respective electrodes. In yet other embodiments where more than two electrodes are provided, each distance at which two electrodes are arranged may be different from another distance at which two electrodes are arranged.

As an illustrative example the distance at which the electrodes are arranged, for instance a gap between two electrodes, may be in a range that corresponds to the length of a respective analyte molecule, such as a nucleic acid molecule. It is noted in this regard that for instance a linearised chromosome may have a length of up to 1.5 m (http://hypertextbook.com/facts/1998/StevenChen.shtml). As a further illustration, already Watson and Crick were able to determine the distance between the two strands of DNA as 2 nanometres. From their DNA model the vertical rise per base pair along the axis of a DNA molecule can be calculated to be 0.34 nm. Typical DNA molecules in human blood plasma have furthermore been reported to be of a length of 100 to 900 inn (http://cat.inist.fr/?aModele=afficheN&cpsidt=2324077). In some embodiments the distance at which the electrodes are arranged is of the same or a smaller length than the length of the analyte molecule. In such embodiments the analyte molecule is capable of spanning the respective gap. A respective distance, e.g. a gap, may for instance have a with selected in the range of about 0.5 nm to about 10 μm, such as a range of about 1 nm, or about 10 nm to about 200 nm, about 300 nm, about 500 nm, about 700 nm, about 800 nm or about 1 μm or 2 μm. As two illustrative examples, a distance of 30 nm may be selected, which would roughly correspond to a length of a linear nucleic acid of about 100 bp. (Such an estimate can be made based on the known helical pitch of ideal A, B and Z DNA for example. B DNA, for example, has a height of 0.34 nm per helical turn and base pair so that 10 base pairs (bp) bridge a distance of 3.4 nm). Alternatively, the distance with can be determined empirically for longer non linear nucleic acids; a distance of 200 nm, may roughly correspond to a length of a nucleic acid of about 2000 to 5000 bp.

As an illustrative example, a nucleic acid molecule as the analyte molecule may be of for instance 100-500 nm, which is for example of a sufficient size of a nucleic acid molecule to includes exemplary genes. The capture molecule may in such an embodiment be immobilised in vicinity to the region in between the electrodes, or even within the respective region. In embodiments where this region in between the electrodes is defined by a small distance separating the electrodes, such as e.g. about 20-about 30 nm, the size of such a nucleic acid analyte molecule will allow the biological analyte molecule to bridge the respective distance between the electrodes (e.g. a gap). Thus, the present invention provides a method by which a single biological analyte molecule can be detected.

The method of the invention includes providing an immobilisation unit. A respective immobilisation unit may be of any material as long as an electrical measurement can be carried out. It may be desired to select the material of the immobilisation unit in order to immobilise a capture molecule thereon (see below). The surface of the immobilisation unit, or a part thereof, may also be altered, e.g. by means of a treatment carried out to alter characteristics thereof. Such a treatment may include various means, such as mechanical, thermal, electrical or chemical means. As an illustrative example, the surface properties of any hydrophobic surface can be rendered hydrophilic by coating with a hydrophilic polymer or by treatment with surfactants. Examples of a chemical surface treatment include, but are not limited to exposure to hexamethyldisilazane, trimethylchlorosilane, dimethyldichlorosilane, propyltrichlorosilane, tetraethoxysilane, glycidoxypropyltrimethoxy silane, 3-aminopropyltriethoxysilane, 2-(3,4-epoxy cyclohexyl)ethyltrimethoxysilane, 3-(2,3-epoxy propoxyl)propyltrimethoxysilane, polydimethylsiloxane (PDMS), γ-(3,4-epoxycyclohexyl)ethyltrimethoxysilane, poly(methyl methacrylate) or a polymethacrylate co-polymer, urethane, polyurethane, fluoropolyacrylate, poly(methoxy polyethylene glycol methacrylate); poly(dimethyl acrylamide), poly[N-(2-hydroxypropyl)methacrylamide] (PHPMA), α-phosphorylcholine-o-(N,N-diethyldithiocarbamyl)undecyl oligoDMAAm-oligo-STblock co-oligomer (cf. e.g. Matsuda, T., et al., Biomaterials, (2003), 24, 4517-4527), poly(3,4-epoxy-1-butene), 3,4-epoxy-cyclohexylmethylmethacrylate, 2,2-bis[4-(2,3-epoxy propoxy)phenyl]propane, 3,4-epoxy-cyclohexylmethylacrylate, (3′,4′-epoxycyclohexylmethyl)-3,4-epoxycyclohexyl carboxylate, di-(3,4-epoxycyclohexylmethyl)adipate, bisphenol A (2,2-bis-(p-(2,3-epoxy propoxy)phenyl)propane) or 2,3-epoxy-1-propanol.

In some embodiments the surface of the immobilisation unit may for instance be coated with an electroconductive polymer, such as polypyrrole (Wang, J., et al., Anal. Chem. (1999) 71, 18, 4095-4099; Wang, J., et al., Anal. Chim. Acta (1999) 402, 7-12), polythiophene, polyaniline, polyacetylene, poly(N-vinyl carbazole), or a copolymer such as a copolymer of pyrrole and thiophene or a copolymer of juglone and 5-hydroxy-3-thioacetic-1,4-naphthoquinone (Reisberg, S., et al., Anal. Chem. (2005) 77, 10, 3351-3356). In embodiments where the immobilisation unit is included in a surface of a carbon paste electrode, it may for example be modified with carboxyl groups by mixing stearic acid with the paste. The linking molecule ethylenediamine may for instance be immobilised on a respective electrode in order to facilitate the subsequent immobilisation of a capture molecule (see below).

The immobilisation unit is arranged within the sensing zone. The sensing zone is usually a region or aperture into which the analyte molecule is caused to be located. As two illustrative examples, the sensing zone may be a region or aperture to which the analyte molecule is caused to flow or into which the analyte molecule is disposed. In typical embodiments the sensing zone is defined by the zone in which an electric field of the pair of electrodes is effective. In some embodiments the immobilisation unit is arranged between two electrodes that are used to generate an electric field (see also below). In some of these embodiments the immobilisation unit is arranged in the gap of a detection electrode. In some embodiments the immobilisation unit is included on an electrode (e.g. a detection electrode). A respective detection electrode may for example be used for the detection of an electric signal in the method of the present invention (see below). As an example, a respective detection electrode may be used for the generation of an electric field. In some embodiments the immobilisation unit is conductively connected to an electrode.

For detecting an analyte molecule, the electrical characteristic of a region in the sensing zone, e.g. the region in between the electrode arrangement, must be influenced by the electrically conducting nanoparticulate tag associated with the capture molecule. For this it is sufficient that that the immobilisation unit, or at least the surface or a part of the surface thereof, is either located in vicinity to the electrodes of the electron pair or in electrical communication, e.g. electrically connected thereto. In these embodiments, the (immobilised) complex of the analyte molecule (in particular a nucleic acid molecule with a larger size, e.g. of several thousands or more base pairs) with the electrically conducting nanoparticulate tag may, for example, swing by Brownian motion with any flexible part (or parts) thereof into the distance in between the electrodes. Alternatively, the electrical interaction between the electrically conducting nanoparticulate tag and an electrical field applied at the electrodes can alone be sufficient to influence the electrical characteristics in the gap in between the electrodes in a detectable manner. In other embodiments the respective immobilisation surface of the immobilisation unit is arranged within the respective region defined by the distance between the (or some of the) electrodes. In some further embodiments the surface of the immobilisation unit is included on an electrode (e.g. a detection electrode). A respective detection electrode may for example be used for the detection of an electric signal in the method of the present invention (see below). As an illustrative example, a respective detection electrode may be used for the generation of an electric field. In some embodiments the surface is conductively connected to an electrode.

As already indicated above, in some embodiments the immobilisation unit is included in or on (e.g. included in the surface of) or conductively connected to an electrode. As an illustrative example, the immobilisation unit may be the surface of a detection electrode or included in the surface of a detection electrode.

In some embodiments the immobilisation unit is located on a semiconductor based transistor or conductively connected thereto. As an example, the surface of the immobilisation unit may be or be included in the surface of a gate electrode of a field effect transistor (FET). In some embodiments the immobilisation unit is conductively connected to the gate electrode of a field effect transistor (FET) as for instance disclosed in US patent application 2006/0029994. The immobilisation unit may also be or included in at least a part of a floating gate electrode of a field effect transistor as described by Barbaro et al. (IEEE Transactions on electron devices [2006], 53, 1, 158-166, see also below). In some embodiments the immobilisation unit is electrically conductive. In other embodiments the immobilisation unit is an electrical insulator, but becomes electrically conductive once a nanoparticulate tag, such as an electroconductive nanoparticle or a plurality of electroconductive nanoparticles, has been immobilised thereon in the method of the present invention (see below). In this regard, the terms “electroconductive”, “electrically conducting” and “electrically conductive”, are used interchangeably herein, and refer to the capability to carry current or otherwise transmit electricity, as opposed to an insulator, the latter having a high electrical resistivity and low electrical conductivity.

The method of the invention further includes providing a capture molecule. Such a capture molecule has an affinity to the analyte molecule and is capable of forming a complex with the analyte molecule. The capture molecule is therefore selected according to the analyte molecule of interest. Examples of a capture molecule include, but are not limited to, a nucleic acid molecule, an oligonucleotide, a protein, an oligopeptide, a polysaccharide, an oligosaccharide, a synthetic polymer, a drug candidate molecule, a drug molecule, a drug metabolite, a metal ion, and a vitamin. As an illustrative example, the capture molecule may be nucleic acid binding polypeptide. In some embodiments the capture molecule may for example be a receptor molecule for an analyte molecule. In such embodiments the receptor molecule and the biological analyte molecule define a specific binding pair (see also below).

Three illustrative examples of suitable capture molecule are biotin, dinitrophenol or digoxigenin. Where the analyte molecule is a protein, a polypeptide, or a peptide, further examples of a capture molecule include, but are not limited to, a streptavidin binding tag such as the STREP-TAGS® described in US patent application US 2003/0083474, U.S. Pat. No. 5,506,121 or 6,103,493, an immunoglobulin domain, maltose-binding protein, glutathione-S-transferase (GST), calmodulin binding peptide (CBP), FLAG-peptide (e.g. of the sequence Asp-Tyr-Lys-Asp-Asp-Asp-Asp-Lys-Gly), the T7 epitope (Ala-Ser-Met-ThrGly-Gly-Gln-Gln-Met-Gly), maltose binding protein (MBP), the HSV epitope of the sequence Gln-Pro-Glu-Leu-Ala-Pro-Glu-Asp-Pro-Glu-Asp of herpes simplex virus glycoprotein D, the Vesicular Stomatitis Virus Glycoprotein (VSV-G) epitope of the sequence Tyr-Thr-Asp-IleGlu-Met-Asn-Arg-Leu-Gly-Lys, the hemagglutinin (HA) epitope of the sequence Tyr-ProTyr-Asp-Val-Pro-Asp-Tyr-Ala and the “myc” epitope of the transcription factor c-myc of the sequence Glu-Gln-Lys-Leu-Ile-Ser-Glu-Glu-Asp-Leu. Where the analyte molecule is a nucleic acid, a polynucleotide or an oligonucleotide, a capture molecule may furthermore be an oligonucleotide. Such an oligonucleotide tag may for instance be used to hybridize to an immobilised oligonucleotide with a complementary sequence (see below). A respective capture molecule may be located within or attached to any other molecule.

A further example of a capture molecule is an immunoglobulin, a fragment thereof or a proteinaceous binding molecule with immunoglobulin-like functions. Examples of (recombinant) immunoglobulin fragments are F_{ab} fragments, Fᵥ fragments, single-chain Fᵥ fragments (scFv), diabodies, triabodies (Iliades, P., et al., FEBS Lett (1997) 409, 437-441), decabodies (Stone, E., et al., Journal of Immunological Methods (2007) 318, 88-94) and other domain antibodies (Holt, L. J., et al., Trends Biotechnol. (2003), 21, 11, 484-490). An example of a proteinaceous binding molecule with immunoglobulin-like functions is a mutein based on a polypeptide of the lipocalin family (WO 03/029462, Beste et al., Proc. Natl. Acad. Sci. USA (1999) 96, 1898-1903). Lipocalins, such as the bilin binding protein, the human neutrophil gelatinase-associated lipocalin, human Apolipoprotein D or glycodelin, posses natural ligandbinding sites that can be modified so that they bind to selected small protein regions known as haptens. Examples of other proteinaceous binding molecules are the so-called glubodies (see e.g. international patent application WO 96/23879 or Napolitano, E. W., et al., Chemistry & Biology (1996) 3, 5, 359-367), proteins based on the ankyrin scaffold (Mosavi, L. K., et al., Protein Science (2004) 13, 6, 1435-1448) or crystalline scaffold (e.g. internation patent application WO 01/04144) the proteins described in Skerra, J. Mol. Recognit. (2000) 13, 167-187, AdNectins, tetranectins and avimers. Avimers contain so called A-domains that occur as strings of multiple domains in several cell surface receptors (Silverman, J., et al., Nature Biotechnology (2005) 23, 1556-1561). Adnectins, derived from a domain of human fibronectin, contain three loops that can be engineered for immunoglobulin-like binding to targets (Gill, D. S. & Dunk, N. K., Current Opinion in Biotechnology (2006) 17, 653-658). Tetranectins, derived from the respective human homotrimeric protein, likewise contain loop regions in a C-type lectin domain that can be engineered for desired binding (ibid.). Peptoids, which can act as protein ligands, are oligo(N-alkyl) glycines that differ from peptides in that the side chain is connected to the amide nitrogen rather than the cc carbon atom. Peptoids are typically resistant to proteases and other modifying enzymes and can have a much higher cell permeability than peptides (see e.g. Kwon, Y.-U., and Kodadek, T., J. Am. Chem. Soc. (2007) 129, 1508-1509). If desired, a modifying agent may be used that further increases the affinity of the respective capture molecule for any or a certain form, class etc. of analyte molecules.

As an illustrative example, the capture molecule may be a metal ion bound by a respective metal chelator, such as ethylenediamine, ethylenediaminetetraacetic acid (EDTA), ethylene glycol tetraacetic acid (EGTA), diethylenetriaminepentaacetic acid (DTPA), N,N-bis(carboxymethyl)glycine (also called nitrilotriacetic acid, NTA), 1,2-bis(o-aminophenoxy)ethane-N,N,N′,N′-tetraacetic acid (BAPTA), 2,3-dimercapto-1-propanol (dimmercaprol), porphine or heme. A respective metal ion may define a receptor molecule for a peptide of a defined sequence, which may also be included in a protein. In line with the standard method of immobilised metal affinity chromatography used in the art, for example an oligohistidine tag of a respective peptide or protein is capable of forming a complex with copper (Cu²⁺), nickel (Ni²⁺), cobalt (Co²⁺), or zink (Zn²⁺) ions, which can for instance be presented by means of the chelator nitrilotriacetic acid (NTA).

The capture molecule, for example a nucleic acid capture molecule, used in the method according to the present invention, may be of any suitable length. In some embodiments the capture molecule is a nucleic acid molecule with a nucleic acid sequence of a length of about 7 to about 30 bp, for example a length of about 9 to about 25 bp, such as a length of about 10 to about 20 bp.

In some embodiments the capture molecule is a PNA molecule. As indicated above, a PNA molecule is a nucleic acid molecule in which the backbone is a pseudopeptide rather than a sugar. Accordingly, PNA generally has a charge neutral backbone, in contrast to DNA or RNA. Nevertheless, PNA is capable of hybridising at least complementary and substantially complementary nucleic acid strands, just as e.g. DNA or RNA (to which PNA is considered a structural mimic).

The method of the invention further includes immobilising the capture molecule on the immobilisation unit, generally on a surface or a part of a surface of an immobilisation unit. The respective surface (or surface part) of the immobilisation unit is arranged within the sensing zone. In some embodiments at least a part of the respective surface of the immobilisation unit is arranged in a zone where an electric field of the pair of electrodes is effective. In some embodiments upon immobilisation of the capture molecule at least a part thereof is included in the region defined by the distance between the (or some of the) electrodes.

The capture molecule may be immobilised on the immobilisation unit at any stage during the present method of the invention. As two examples, it may be immobilised at the beginning of the method or before adding an electroconductive nanoparticle (see below). In typical embodiments it is immobilised before performing an electrical measurement (see below). The capture molecule may be immobilised by any means. It may be immobilised on the entire surface of the immobilisation unit, or a selected portion of the surface of e.g. the detection electrode. In some embodiments the capture molecule is provided first and thereafter immobilised onto the immobilisation unit. An illustrative example is the mechanical spotting of a nucleic acid capture molecule onto the immobilisation unit. This spotting may be carried out manually, e.g. by means of a pipette, or automatically, e.g. by means of a micro robot. As an illustrative example, a protein capture molecule, a peptide capture molecule or the polypeptide backbone of a PNA capture molecule may be covalently linked to a gold detection electrode via a thio-ether-bond.

In embodiments where both the capture molecule used in the present invention and the analyte molecule are a nucleic acid molecule, including an oligonucleotide, the capture molecule typically has a nucleotide sequence that is at least partially complementary to at least a portion of a strand of the analyte molecule.

If desired, more than one capture molecule may be immobilised. This may for instance be desired in order to broadly screen for the presence of any of a group of selected analyte nucleic acid sequences. The use of more than one capture molecule may also be desired for the detection of the same analyte molecule via different regions thereof, e.g. different haptens of a protein or different recognition sequences of a nucleic acid molecule, e.g., the 5′- and 3′-termini thereof, which enhances the likelihood to detect even a few copies of a biological analyte (e.g. nucleic acid) molecule in a sample.

If desired, more than one capture molecule may be immobilised on the electrode. This may for instance be desired in order to broadly screen for the presence of any of a group of selected nucleic acid sequences, e.g. where the biological analyte molecule is a nucleic acid molecule. This may also be desired to allow for the simultaneous or consecutive detection of different analytes such as two or more genomic DNAs, each of them having binding specificity for one particular type of capture molecule. In some embodiments similar nucleic acid sequences, e.g. a number of nucleic acid sequences that are partially or substantially complementary to a selected nucleic acid analyte molecule, may be immobilised in order to enhance the likelihood of detecting the respective nucleic acid analyte molecule. Where desired, a further selectivity may be introduced by the selection of the nucleic acid molecule used that is attached to the enzyme added (see below). Furthermore, in this manner the detection of the same nucleic acid analyte molecule via different recognition sequences can be achieved, e.g., the 5′- and 3′-termini of a nucleic acid molecule, which enhances the likelihood to detect even a few copies of a nucleic acid analyte molecule in a sample. Two or more capture molecules may also be desired in order to be able to detect two or more analyte molecules. In some embodiments of the method of the invention the presence of one analyte molecule may also provide confirmation of the presence of another analyte molecule.

In some embodiments the capture molecule is immobilised on the immobilisation unit via a covalent bond. In some embodiments a linking molecule may be used to attach the capture molecule to the immobilisation unit (see also above). Any molecule with a reactive moiety that is capable of undergoing a reaction with a corresponding moiety of an analyte molecule may be used. As an illustrative example, a linking molecule may be an aliphatic compound with a backbone of 4-50 carbon atoms, of which some may be exchanged by N, O, Si or S atoms, and a reactive functional group. Examples of reactive functional groups include, but are not limited to, aldehydes, carboxylic acids, esters, imido esters, anhydrides, acyl nitriles, acyl halides, acyl azides, isocyanates, sulphonate esters, sulfonyl halides, or aryl halides, which may for example react with an amino group of a capture molecule, or alkyl sulphonates, aryl halides, acrylamides, maleimides, haloacetamides or aziridines, which may for example react with a thio group of a capture molecule or a carboxylic acid, an anhydride, an isocyanate, a phosphoramidite, a halotriazine, an acyl halide, an acyl nitrile, an alkyl halide, an alkyl sulphonate or a maleimide, which may for example react with a hydroxy group of a capture molecule.

Any of the above examples of a capture molecule may also serve as a linker for the immobilisation of another capture molecule. This may for example be desired to obtain a capture molecule that has a chosen degree of specifity for a selected analyte molecule. Avidin or streptavidin may for instance be employed to immobilise a biotinylated nucleic acid, or a biotin containing monolayer of gold may be employed (Shumaker-Parry, J. S., et al., Anal. Chem. (2004) 76, 918). As another illustrative example, the capture molecule may be a metal ion bound by a respective metal chelator (see above). A capture molecule that is capable of forming a complex with a desired analyte molecule may then be equipped with an affinity tag for such a metal ion by means of genetic engineering. Upon contacting the ion, which is immobilised on the immobilisation unit via the respective metal chelator with such a capture molecule, the capture molecule is immobilised on the immobilisation unit. As yet another illustrative example, a nucleic acid capture molecule may be locally deposited, e.g. by scanning electrochemical microscopy, for instance via pyrrole-oligonucleotide patterns (e.g. Fortin, E., et al., Electroanalysis (2005) 17, 495). It is understood that in other embodiments a nucleic acid capture molecule may be directly synthesized on the immobilisation unit, for example using photoactivation and deactivation.

The surface of the immobilisation unit may be activated prior to immobilising the capture molecule thereon, for instance in order to facilitate the attachment reaction (see also above). If a glass surface is used, it may for example be modified with aminophenyl or aminopropyl silanes. 5′-succinylated nucleic acid capture molecules may for instance be immobilised thereon by carbodiimide-mediated coupling. In some embodiments the surface of the immobilisation unit may for instance be coated with an electroconductive polymer, such as polypyrrole (Wang, J., et al., Anal. Chem. (1999) 71, 18, 4095-4099; Wang, J., et al., Anal. Chim. Acta (1999) 402, 7-12), polythiophene, polyaniline, polyacetylene, poly(methacrylamide), poly(N-vinyl carbazole), or a copolymer such as a copolymer of pyrrole and thiophene or a copolymer of juglone and 5-hydroxy-3-thioacetic-1,4-naphthoquinone (Reisberg, S., et al., Anal. Chem. (2005) 77, 10, 3351-3356). In embodiments where a surface of the immobilisation unit is included in the surface of a carbon paste electrode, it may for example be modified with carboxyl groups by mixing stearic acid with the paste. A capture molecule may be immobilised on a respective electrode by means of linking molecule ethylenediamine.

After immobilising the capture molecule on the immobilisation unit, any remaining capture molecule, or molecules, that were not immobilised may be removed from the immobilisation unit. Removing an unbound capture molecule may be desired to avoid subsequent complex formation of such capture molecule with the analyte molecule, which might reduce the sensitivity of the present method. Removing an unbound capture molecule may also be desired to avoid a non-specific binding of such capture molecule to any matter present in a sample used, which might for instance alter the electric properties of such matter (e.g., reducible metal cations), which might interfere with the results of the electrical measurement (see also below). An unbound capture molecule may for instance be removed by exchanging the medium, e.g. a solution that contacts the detection electrode.

If desired, a blocking agent may be immobilised on the immobilisation unit. This blocking agent may serve in reducing or preventing non-specific binding of matter included in the solution suspected to include the analyte molecule. It may also serve in reducing or preventing non-specific binding of any other matter, such as a molecule or solution that is further added to the detection electrode when carrying out the method of the invention.

The blocking agent may be added together with the capture molecule or subsequently thereto. Any agent that can be immobilised on the electrode and that is able to prevent (or at least to significantly reduce) the non-specific interaction between undesired molecules, i.e. molecules the detection of which is undesired, and the capture molecule is suitable for that purpose, as long as the specific interaction between the capture molecule and the biological analyte molecule is not prevented. Examples of such agents are thiol molecules, disulfides, thiophene derivatives, and polythiophene derivatives. An, illustrative example of a useful class of blocking reagents are thiol molecules such as 16-mercaptohexadecanoic acid, 12-mercaptododecanoic, 11-mercaptodecanoic acid or 10-mercaptodecanoic acid.

The term “derivative” as used herein thus refers to a compound which differs from another compound of similar structure by the replacement or substitution of one moiety by another. Respective moieties include, but are not limited to atoms, radicals or functional groups. For example, a hydrogen atom of a compound may be substituted by alkyl, carbonyl, acyl, hydroxyl, or amino functions to produce a derivative of that compound. Respective moieties include for instance also a protective group that may be removed under the selected reaction conditions.

The method of the present invention further includes contacting the immobilisation unit with a solution suspected to include the analyte molecule (see also above). The immobilisation unit may for example be immersed in a solution, to which the solution suspected to include the analyte acid molecule is added. In some embodiments both such solutions are aqueous solutions. In one embodiment the entire method is carried out in an aqueous solution. The method further includes allowing the analyte molecule to form a complex with the capture molecule on the immobilisation unit. As an illustrative example, where the capture molecule is an ion that is forming a complex with a chelate molecule, the method may include the formation of coordinative bonds between the metal ion and an affinity tag, such an oligohistidine tag, of the analyte molecule. As a further illustrative example, where both the capture molecule and the analyte molecule are nucleic acid molecules, the method includes allowing the analyte molecule to hybridise to the PNA capture molecule on the electrode. If the solution contains a plurality of different analyte molecules to be detected, the conditions are chosen so that the analyte molecules can either bind simultaneously or consecutively to their respective capture molecules.

In the above example of a nucleic acid molecule or an oligonucleotide as an analyte molecule, a single-stranded nucleic acid molecule may for example be selected as the capture molecule. The respective single-stranded nucleic acid molecule may have a nucleic acid sequence that is at least partially complementary to at least a portion of a strand of the nucleic acid molecule that is the analyte molecule. The respective nucleotide sequence of the capture molecule may for example be 70, for example 80 or 85, including 100% complementary to another nucleic acid sequence. The higher the percentage to which the two sequences are complementary to each other (i.e. the lower the number of mismatches), the higher is typically the sensitivity of the method of the invention (see FIG. 7). In typical embodiments the respective nucleotide sequence is substantially complementary to at least a portion of the analyte molecule. “Substantially complementary” as used herein refers to the fact that a given nucleic acid sequence is at least 90, for instance 95, such as 100% complementary to another nucleic acid sequence. The term “complementary” or “complement” refers to two nucleotides that can form multiple favourable interactions with one another. Such favourable interactions include Watson-Crick base pairing. As an illustrative example, in two given nucleic acid molecules (e.g. DNA molecules) the base adenosine is complementary to thymine, while the base cytosine is complementary to guanine. A nucleotide sequence is the complement of another nucleotide sequence if all of the nucleotides of the first sequence are complementary to all of the nucleotides of the second sequence. Accordingly, the respective nucleotide sequence will specifically hybridise to the respective portion of the nucleic acid analyte molecule under suitable hybridisation assay conditions, in particular of ionic strength and temperature.

In some embodiments the analyte molecule includes a pre-defined sequence. The sequence may for example be a sequence of amino acids, nucleic acids or saccharides. In some embodiments the analyte nucleic acid molecule furthermore includes at least one single-stranded region. In such embodiments it may be desirable to select a single-stranded region as the predefined sequence. In this case the capture molecule can directly form Watson-Crick base pairs with the analyte molecule, without the requirement of separating complementary strands of the nucleic acid analyte molecule. Where the nucleic acid molecule that is the analyte molecule, or a region thereon that includes e.g. a predefined sequence, is provided or suspected to be in double strand form, the respective nucleic acid duplex may be separated by any standard technique used in the art, for instance by increasing the temperature (e.g. 95° C., see also the Examples below). In embodiments where multiple sequences may be included in the analyte nucleic acid molecule, multiple respective capture molecules may be used, each of which being at least partially complementary to e.g. a selected portion of the nucleic acid analyte molecule (see also below).

As explained above, in embodiments where both the analyte molecule and the capture molecule are a nucleic acid molecule, the capture molecule is typically a single-stranded nucleic acid molecule. By hybridisation of the two nucleic acid molecules, i.e. the capture molecule and the analyte molecule, a complex is formed. It is understood that for the quantification of such a nucleic acid molecule a plurality of the respective capture molecules is usually required. In a suitable concentration range of the analyte molecule, where the method of the invention can be used to quantify a respective analyte molecule, generally an excess of capture molecules in comparison to analyte molecule is required. As a result, one or more single-stranded nucleic acid capture molecules, which do not form a complex with an analyte molecule, may remain. Depending on the electroconductive nanoparticles used, the presence of such a nucleic acid capture molecule may interfere with the detection of the method of the present invention. In particular where the nucleic acid capture molecule is a single-stranded DNA molecule or a single-stranded RNA molecule, such a remaining nucleic acid molecule may be removed from the immobilisation unit.

In such embodiments the immobilisation unit may be contacted with at least one enzyme with nuclease activity, in order to remove any nucleic acid capture molecule that has not hybridised to an analyte molecule. It may be desired to reduce or block nuclease activity that is directed against double-strands of nucleic acids in order to avoid a reduction of detection signal, caused by the degradation of complexes of capture molecule and analyte. In some embodiments an enzyme may be selected that selectively degrades single-stranded nucleic acids. Examples of such enzymes include, but are not limited to, mung bean nuclease, nuclease P1 (e.g. from fungi), nuclease S1 (e.g. from fungi), CEL 1 nuclease (e.g. from plants), recJ exonuclease (e.g. from E. coli), and a DNA polymerase that is capable of degrading single-stranded DNA due to its 5′->3′ exonuclease activity and a DNA polymerase that is capable of degrading single-stranded DNA due to its 3′-5′ exonuclease activity.

The method of the present invention further includes providing a nanoparticulate tag. The nanoparticulate tag may include or consist of an electroconductive nanoparticle or a plurality thereof. Examples of a suitable nanoparticle include, but are not limited to, a nanocrystal, a nanosphere, a nanorod, a nanotube, a nanowire and a nanocup. A variety of particle sizes with a diameter in or below the nanometer range are suitable for the method of the present invention. While the use of particles of larger diameter, e.g. microparticles may also be tested if desired, the use of nanoparticles is recommended due to their large surface-tovolume ratio, their biocompatibility, high reactivity and their tailorable physicochemical properties. A respective nanoparticle may for instance have a diameter of about 0.1 nm to about 1 μm, such as about 1 nm to about 700 nm or about 20 nm to about 500 nm. The electroconductive nanoparticle has an affinity for the analyte molecule. This is due to the fact that it includes or consists of electroconductive matter that has an affinity to the analyte molecule. The electrically conducting matter can interact chemically with the analyte molecule. A chemical interaction, which is generally an intermolecular interaction and typically creates an attractive force, may include the formation of non-covalent or covalent bonds, including van der Waals force, polar interaction (such as dipole-dipole interaction or ionic interaction), complex formation, etc. The electroconductive particle may for example include or consist of a metal or a metalloid such as a metal oxide or a metal hydroxide. The metal or metalloid has an affinity for the analyte molecule.

The electroconductive nanoparticle may also include a dopant. The term “dopant” as used herein means matter, in particular atoms, that is present in small amounts, typically in the parts per million (ppm) to percent range, in order to change the properties of the nanoparticle, in particular in order to alter the electrical properties of e.g. the metal or metalloid. As an illustrative example, the nanoparticle may include, or consist at least largely of, a metalloid that is a semiconductor. In such embodiments a dopant may be added in order to shift the Fermi level (an electron energy level) of the semiconductor, whereby the level of conductivity of the semiconductor is altered. A respective dopant may be either an electron acceptor or an electron donor. A semiconductor doped with a donor dopant is known in the art as being “n-type”, whereas a semiconductor doped with an acceptor dopant is known as “ptype”. The use of a dopant may be desired depending on the conductivity of a selected metalloid. It is noted in this regard that some metalloids such as indium tin oxide already have a nearly metallic electrical conductivity as such.

Those skilled in the art will appreciate that the method of the present invention uses a nanoparticulate tag such as a nanoparticle that includes matter with an affinity for an analyte molecule in itself, rather than relying on affinity tags that need to be immobilised on the nanoparticle. The use of affinity tags (see e.g. Luo, X., et al., Electroanalysis [2006], 18, 319-326; or Rosi, N. L. Chem. Rev. [2005] 105, 1547-1562) bears in particular the disadvantages of introducing complexity into a detection method, restructuring the surface of the particle, and of reducing the available particle surface to certain moieties of affinity tags attached thereto. UK patent application GB 2 401 948 for example discloses a method of measuring the binding of an analyte molecule to a probe substance by means of electrically conductive nanoparticles. The nanoparticles used in the method of this publication are covalently bound to DNA adhesion molecules.

In some embodiments the metal or metalloid is capable of forming a complex with the analyte molecule via negative charges, which are present on the surface of the analyte molecule, such as a polysaccharide, a nucleic acid or a protein. As an illustrative example, a metal oxide or a metal hydroxide may have an affinity to phosphate and/or phosphonate. Such a metal oxide is therefore able to associate with proteins or nucleic acid molecules that contain phosphate or phosphonate groups. A number of proteins are for example covalently modified with phosphate groups as a result of the action of enzymes with phosphotransferase activity. Respective enzymes may be activated by certain events of a cellular signal transduction cascade. As two further examples, DNA and RNA molecules contain a phosphate backbone. Nanoparticles that contain or consist of a respective metal oxide associate to the backbone of a nucleic acid molecule. Nucleic acid alkyl or aryl phosphonates analogues may for example be included in DNA mimics, such as analogues of peptide nucleic acids.

Examples of a suitable metal oxide with an affinity to phosphate and/or phosphonate include, but are not limited to indium tin oxide, titanium oxide, tantalum oxide, copper oxide and zinc oxide. Examples of a suitable metal hydroxide with an affinity to phosphate and/or phosphonate include, but are not limited to aluminiumhydroxide, titanium hydroxide, copper hydroxide and gold hydroxide Au(OH)₃. Phosphonic acids have for example been shown to adsorb to many metal oxides such as copper oxide, silver oxide, titanium oxide, aluminium oxide, zirconium oxide or ferric oxide and to form monolayers thereon (Follcers, J. P. et al. Langmuir [1995] 11, 813-824). The adsorption and self-assembly of a monolayer of octadecylphosphoric acid on a surface tantalum oxide Ta₂O₅ has for instance been reported, which has been suggested to be based on coordinative bonds (Brovelli, D., et al., Langmuir [1999] 15, 4324-4327; Textor, M., et al., Langmuir [2000] 16, 3257-3271). It has been speculated that an oxide ion in the Ta₂O₅ surface is being replaced by phosphate via a protonation of the oxide (Textor et al., 2000, supra), as schematically summarised by the scheme:

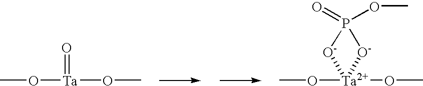

As a further example, DNA has been found to associate to indium tin oxide surfaces (abstract Q1.00105 of 2006 March meeting of the American Physical Society).

The electro conductive nanoparticles may in some embodiments be able to form a complex with the analyte molecule via a coordinative bond. A respective coordinative bond may in some embodiments be formed between metal atoms of a metal or metal oxide of the nanoparticle. In other embodiments the coordinative bond may include an activation agent. It may for example be formed by a reaction with the activation agent. The activation agent may likewise include a metal atom, such as a transition metal atom, or a metalloid atom such as a silicon atom. It may for example be a transition metal compound such as a zirconium compound or a niobium compound. Zirconium is for example known to coordinatively achieve the association of a phosphate- to a carboxylate moiety or of different phosphate moieties (Mazur, M., et al. Langmuir [2005] 21, 8802-8808; Lee, H., et al., J. Phys. Chem. [1998] 92, 2597-2601).

An illustrative example of a suitable zirconium compound is zirconyl chloride. Previously it has been shown that oligonucleotides can be immobilised on a glass surface that was coated with indium tin oxide (Zeng, J., & Krull, U. J., Chimica Oggi [2003] 21, 10/11, 48-52), when zirconyl chloride octahydrate and either sodium sulphate or 4-formylphenyl phosphate were employed. The formation of zirconium sulphate using sodium sulphate, and the formation of aldehyde moieties on the immobilisation unit using formylphenyl phosphate apparently resulted in the immobilisation of oligonucleotides. However, as illustrated in the examples below, zirconyl chloride can also be employed as an activation agent for the formation of a complex between nucleic acids and e.g. a metal oxide such as indium tin oxide. In this form it can be used in the absence of sulphate or aldehyde moieties. Further examples of compounds suitable as an activation agent include, but are not limited to, silica (SiO₂), titania (TiO₂) or niobium oxide (Nb₂O₅).

The method of the present invention further includes adding the electrically conductive nanoparticle. Thereby the electrically conductive nanoparticle is allowed to associate to the complex formed between the capture molecule and the analyte molecule (see above). As an illustrative example, a high strength of transition metal-phosphate bonds is known in the art (see e.g. Textor et al, 2000, supra). A nanoparticle that includes a metal or a metalloid, such as a metal oxide, and a transition metal compound (see above) will therefore generally associate with a nucleic acid molecule that, as an analyte molecule, forms a complex with a capture molecule, such as a nucleic acid binding peptide or protein.

As a further illustrative example, the analyte molecule may be a protein or a polypeptide to which the electroconductive nanoparticle has an affinity. Such a protein or peptide may for example be phosphorylated. In a mixture of proteins and/or peptides phosphorylated proteins and peptides for instance selectively associate to Al(OH)₃ (Wolschin, A et al. Proteomics [2005] 5, 4389-4397). This association can be used in metal oxide affinity chromatography, where only marginal amounts of non-phosphorylated protein bind to a respective metal hydroxide (ibid.). Other examples of such a protein or peptide bind to a metalloid via a specific amino acid sequence. A respective amino acid sequence is Arginine-X—X-Arginine, wherein X is any amino acid (That, C. K. et al., Biotechnology and Bioengineering [2004]87, 2, 129-137). In some embodiments a further discrimination between selected metal oxides according to the respective amino acid sequence can be taken. The sequence ArginineX-Arginine-Arginine, wherein X is any amino acid, for example characterises peptides and proteins that associate particularly well to copper oxide, while the sequence Arginine-X-XArginine-Lysine, wherein X is any amino acid, characterises peptides and proteins that associate particularly well to zinc oxide (ibid).

The method of the present invention further includes determining the presence of the analyte molecule based on an electrical characteristic of a region in the sensing zone. As an example, the immobilisation unit may be exposed to an electric field. The electric field may be generated by any means. It may in some embodiments be generated between two or more electrodes, such as in a two-, three- or four-electrode cell. Respective electrodes may be of any dimension, as long as an electric field can be generated that is sufficient to induce an electric signal caused by the electroconductive nanoparticle (see below). As already indicated above, in some embodiments the immobilisation unit may for example be part of the immobilisation unit of a respective electrode. In other embodiments it may be located in the gap between respective electrode.

In yet other embodiments the electric field is generated by a field effect transistor (FET), more specifically by two electrodes a field effect transistor, termed the ‘source’ and the ‘drain’. Field effect transistors are unipolar transistors in that only one type of charge, such as electrons, generates a current. A FET can be used to switch, to enhance or to deplete a current. In a FET current flows along a ‘channel’ region, which is a semiconductor path in a substrate. The conductivity of a (typically underlying) channel region in a semiconductor material of the substrate is controlled by the electric field that is generated by the source and the drain. A control electrode, the ‘gate’, is capable of varying this conductivity in that a voltage applied between the gate and source terminals modulates the current between the source and drain terminals. A small change in gate voltage can result in a large change in the current from the source to the drain. A fourth terminal of a FET is the bulk, which may be internally connected to the source. A difference between the voltages of the source and body will change the threshold voltage.

Examples of a FET that may be used in the method of the invention include, but are not limited to, a metal oxide-semiconductor field-effect transistor (MOSFET), including a floating gate MOSFET, a junction field-effect transistor (WET) or a metal-semiconductor field-effect transistor (MESFET). A MOSFET has a gate electrode of a metal, which is separated from the substrate by an insulating layer (gate dielectric). A respective MOSFET may also be double-gated, such that the metal oxide-semiconductor gate is formed on two, three or four sides of the channel or wrapped around the channel, for example a FinFET.

The binding of an electroconductive nanoparticle to the complex formed between the capture molecule and the analyte molecule may lead to a change in an electronic charge density or a potential, thereby modulating the current between the source and drain of a FET. As already indicated above, the surface of the immobilisation unit on which the capture molecules are immobilised, may be located on or in vicinity to a FET. Generally this surface is or includes the active region of a FET, which is the region from which a signal is detected in response to the binding of an electroconductive nanoparticle to the complex formed between the capture molecule and the analyte molecule. Typically the active region is the area overlaying the portion of the FET that can be influenced by charge or chemical potential. The “active region” is not to be confused with the “active area,” or doped well in which a transistor is defined. The active area of e.g. a MOS transistor equals the product of its channel width and length. In some embodiments the active region of the sensor is at least a part of the gate of a transistor. In some embodiments where a MOSFET is used, the active region may include the insulating layer over the channel region in the absence of a gate electrode. In such embodiments the complex of the capture molecule and the analyte molecule is completed to form a gate once an electroconductive nanoparticle has associated to this complex. In some embodiments the active region is located on the floating gate of a field effect transistor or on a semiconductor that is connectively connected to a field effect transistor. In such embodiments the capture molecule may be immobilised on the active region (e.g. the floating gate). The binding of a nanoparticle to the complex formed between the capture molecule and the analyte molecule may then activate the active region by charge induction. As a result, charge separation in a semiconductor of the active region may occur. Where the active region is conductively connected to the gate of a field effect transistor (see e.g. Krause, M, et al., Sensors and Actuators B (2000) 70, 101-107; US patent application 2006/0029994), the charge may be transferred to this gate. Where the active region is a floating gate the occurring charge may generate a voltage drop between the substrate and the floating-gate, which in turn may activate the field effect transistor. A control gate with the role of a reference electrode may be included in such a FET as described by Barbaro et al. (2006, supra).

As already indicated above, once the immobilisation unit is exposed to an electric field, the nanoparticle immobilised thereon via its association to the complex of analyte molecule and capture molecule is likewise exposed to the respective electric field. This results in an electric signal caused by the electroconductive nanoparticle. The nanoparticle may for instance change the electric field, change the conductivity or resistance of a medium in the electric field, obtain a charge, transfer charge or conduct a current.

In the method of the invention a signal of the electrically conducting nanoparticulate tag may be detected using any detection technique. In this regard any electrical characteristic of a region in the sensing zone may be used for detection purposes as long as the electrical characteristic is influenced by the electrically conducting nanoparticulate tag. The respective region in the sensing zone may for example be a region in between the electrodes. A detection according to the invention may or instance include a measurement of a conductance, a voltage, a current, a capacitance or a resistance. As an illustrative example, conductance may be measured by linear cyclic voltammetry, square wave voltammetry, normal pulse voltammetry, differential pulse voltanunetry and alternating current voltammetry. As a further example already explained above, the immobilisation unit, or at least a part of the surface thereof, may be exposed to an electric field. In this case the electrically conducting nanoparticulate tag immobilised thereon is likewise exposed to the respective electric field. This results in an electric signal caused by the electroconductive polymer. Accordingly, in some embodiments of the method of the invention an electric field is generated, which may in some embodiments be a symmetric or a homogenous electric field. The electric filed may for example be an external field. It may also be generated at least one electrode of the pair of electrodes.

This signal of the electroconductive nanoparticle is detected in the method of the present invention. Any detection technique for electric signals may be used in the method of the present invention. A detection according to the invention may or instance include a measurement of a conductance, a voltage, a current, a capacitance or a resistance. As an illustrative example, conductance may be measured by linear cyclic voltammetry, square wave voltammetry, normal pulse voltammetry, differential pulse voltammetry and alternating current voltammetry.

In some embodiments more than one nanoparticle, in particular a plurality of nanoparticles, is added. In such embodiments the plurality of electroconductive nanoparticles is allowed to associate to the complex formed between the capture molecule and the analyte molecule. It has been observed by the present inventors that the use of more than one nanoparticles is typically accompanied by an increase in signal intensity and signal to noise ratio. In some of these embodiments an electroconductive network of electroconductive nanoparticles may be formed. The network is associated with the complex formed between the capture molecule and the analyte molecule. Atomic force microscopy of an oligonucleotide labelled particle has for instance shown that 2 to 3 oligonucleotides (rather than only one) bind to a respective nanoparticle (Rajh, T., et al., Nano Letters [2004] 6, 1017-1023). Accordingly, a nanoparticle used in the present invention is likewise capable of associating with more than one analyte molecule at the same time. A plurality of electroconductive nanoparticles may therefore connect a plurality of analyte molecules, if present. In particular where the analyte molecules are electrically conductive, an electroconductive network is obtained. In other embodiments the number of electroconductive nanoparticles is high enough to bring them into close vicinity, likewise with the result of an electroconductive network. In any such embodiment the method also includes detecting an electric signal caused by the electroconductive network of the electroconductive nanoparticles in the electric field. Such a signal is significantly amplified when compared to the signal of a single electroconductive nanoparticle. As long as about the same number of electroconductive nanoparticles is used in measurements that are compared, the electric signal generated from a respective network nevertheless directly correlates to the concentration of analyte molecules in a sample solution.

In some embodiments a respective electroconductive network is conductively connected to the surface of the immobilisation unit (which may be electrically conductive, see above) or to another surface that is for instance the surface of an electrode. As an illustrative example, the electroconductive network may bridge across the gap between two electrodes, e.g. of a detection electrode.

Where desired, several different analyte molecules may be analysed at the same time using either the same immobilisation unit or several immobilisation units in parallel. In embodiments where several analyte molecules are analysed using the same immobilisation unit, different capture molecules may be immobilised on the immobilisation unit (see above). Where a plurality of each respective capture molecule is used, the number and/or density of each respective capture molecule may be independently selected.

If desired, further methods for detection may be employed. As an example, an optical detection may also be performed or enhanced by means of an optically amplifying conjugated polymer, e.g. in a Förster energy transfer system (Gaylord, B. S., et al., Proc. Natl. Acad. Sci. USA (2005) 102, 34-39; Gaylord, B. S., et al., J. Am. Chem. Soc. (2003) 125, 896-900). As a further example, a cationic polythiophene may be added, which changes its color and fluorescence in the presence of single-stranded or double-stranded nucleic acid molecules (Ho, H. A., et al., J. Am. Chem. Soc. (2005) 127, 36, 12673-12676). Immunoglobulins labeled with a fluoresce dye may for instance be used to optically detect the presence of a certain protein or polypeptide. Nucleic acid intercalating dyes, such as YOYO, JOJO, BOBO, POPO, TOTO, LOLO, SYBR, SYTO, SYTOX, PicoGreen, or Oligreen as available from Molecular Probes, may be used for optical detection.

In typical embodiments, the result obtained is then compared to that of a control measurement. In a respective control measurement a capture molecule unable to bind the analyte molecule may for instance be used. Two examples of such a “control” capture molecule are an oligosaccharide molecule and a nucleic acid molecule having a sequence not complementary to any portion of the respective analyte molecule. If the two electrical measurements, i.e. “sample” and “control” measurement, differ in such a way that the difference between the values determined is greater than a pre-defined threshold value, the sample solution contained the relevant analyte molecule.

In some embodiments, the method is designed in such a way that a reference measurement and a measurement for detecting an analyte molecule are performed simultaneously. This may for instance be done by carrying out a reference measurement only with a control medium and, at the same time, a measurement with the sample solution suspected to contain the analyte molecule to be detected. Likewise, a respective control measurement with an analyte molecule that has for example comparable properties (e.g. a protein of comparable size) but that cannot define a specific binding pair with the capture molecule may be carried out in parallel to a measurement for detecting an analyte molecule.

The present method also allows detecting more than one an analyte molecule simultaneously or consecutively in a single measurement. For this purpose, a plurality of immobilisation unit as described above may for example be used; wherein different types of capture molecules, each of which capable of defining a specific binding pair with an analyte molecule, are immobilised on each immobilisation unit. Alternatively, a plurality of capture molecules, each of which capable of defining a specific binding pair with an analyte molecule, may be immobilised on a single surface of an immobilisation unit or on a small number of such surfaces.

The methods according to the present invention may be a diagnostic method for the detection (including quantification) of one or more proteins, protein modifications, polysaccharides, combinations of proteins and oligo- or polysaccharides, nucleic acids or genes. The analyte molecule may for instance be involved in or associated with a disease or a state of the human or animal body that requires prophylaxis or treatment.

The method of the invention may be combined with other analytical and preparative methods. As already indicated above, the biological analyte molecule may in some embodiments for instance be extracted from matter in which it is included. Examples of other methods that may be combined with a method of the present invention include, but are not limited to isoelectric focusing, chromatography methods, electrochromatographic, electrokinetic chromatography and electrophoretic methods. Examples of electrophoretic methods are for instance free flow electrophoresis (FFE), polyacrylamide gel electrophoresis (PAGE), capillary zone or capillary gel electrophoresis. Furthermore the data obtained using the present invention may be used to interact with other methods or devices, for instance to start a signal such as an alarm signal, or to initiate or trigger a further device or method.

The present invention also provides a kit for detecting a biological analyte molecule, which may for instance be a diagnostic kit. A respective kit includes a pair of electrodes, which are arranged at a distance from one another, for example separated by a gap. The pair, of electrodes is arranged within a sensing zone. A kit according to the present invention furthermore includes an immobilisation unit. The surface of the immobilisation unit is arranged within the sensing zone. As explained above, the sensing zone may for example be defined by the zone in which an electric field of said pair of electrodes is effective.

The kit also includes a capture molecule. The capture molecule has an affinity to the analyte molecule and is capable of forming a complex with the analyte molecule. As an example, where the analyte molecule is a nucleic acid molecule, the capture molecule may be a nucleic acid molecule that includes a nucleotide sequence that is at least partially complementary to at least a portion of the nucleic acid analyte molecule. The kit also includes an electrically conducting nanoparticulate tag. As explained above, the nanoparticulate tag may for example be or include one or more electrically conducting nanoparticles such as a nanocrystal, a nanosphere, a nanorod, a nanotube, a nanowire or a nanocup. The electrically conducting nanoparticulate tag includes or consists electrically conducting matter that is capable of chemically interacting with the analyte molecule (see above). In some embodiments the kit further includes instructions for electrically detecting (including quantifying) the biological analyte molecule.

A respective kit may furthermore include means for immobilising the capture molecule to the surface of the immobilisation unit. As explained above, a nucleic acid capture molecule included in the kit may have a moiety that allows for, or facilitates, an immobilisation on a respective immobilisation unit. The kit may also include a linking molecule. As an illustrative example, 6-mercapto-1-hexanol may be included in the kit. Where the capture molecule is a nucleic acid molecule, the capture molecule may upon using the kit be 5′-C₆H₁₂SH-modified (see above for examples).

A respective kit may be used to carry out a method according to the present invention. It may include one or more devices for accommodating the above components before, while carrying out a method of the invention, and thereafter. As an illustrative example, it may include a microelectromedical system (MEMS).

In order that the invention may be readily understood and put into practical effect, particular embodiments will now be described by way of the following non-limiting examples.

### Exemplary Embodiments of the Invention

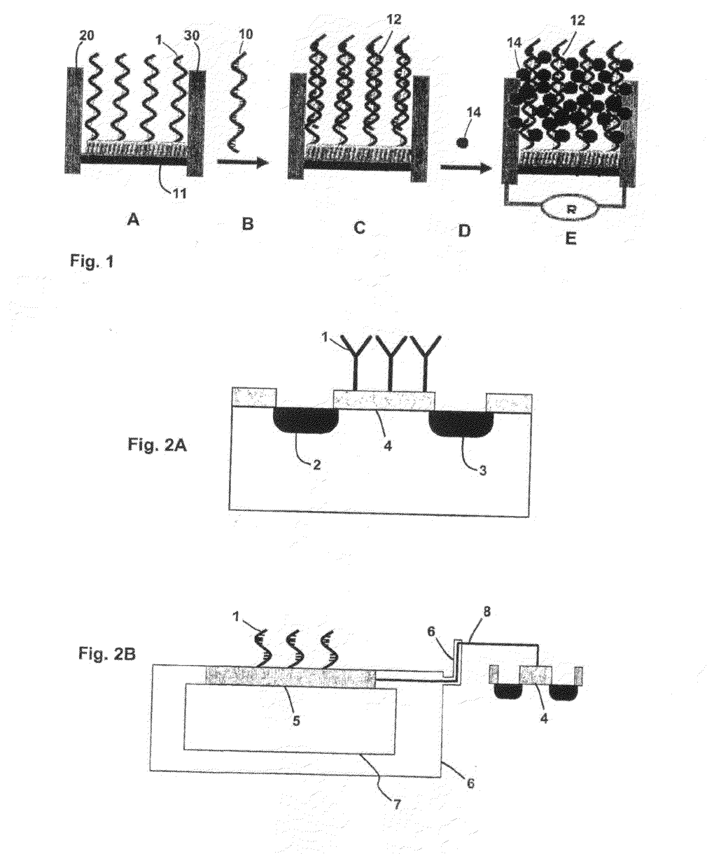

FIG. 1 depicts a schematic representation of a nucleic acid biosensor based on in situ labeling of a hybridized analyte nucleic acid molecule with an electroconductive nanoparticulate tag. On an immobilisation unit (11) a capture molecule (1) is immobilised (A) and contacted with a solution suspected to include the analyte molecule (10) (B), such that a complex (12) between analyte molecule and capture molecule is formed (C). In the depicted embodiment the immobilisation unit is arranged between the two electrodes (20, 30). An electrically conducting nanoparticulate tag (14) is added (D). Based on an electrical characteristic of a region in the sensing zone, which is influenced by the nanoparticulate tag (14), the presence of the analyte molecule is determined (E).

FIG. 2 depicts a schematic representation of a protein biosensor (A, C) and a further nucleic acid biosensor (B) according to the present invention. In FIG. 2A capture molecules (1) are immobilised on the gate electrode (4) of a field effect transistor, which further includes a source (2) and a drain (3). FIG. 2B depicts an embodiment where the capture molecules are immobilised on a sensing unit of an extended gate field effect transistor, which includes a semiconductor (5) on a conductive substrate additional, surrounded by an insulator (6). Via a conductive wire the semiconductor (5) is connected to the gate (4) of a MOSFET. FIG. 2C depicts an embodiment where the capture molecules are immobilised on an additional, electrically floating gate (9) of a field effect transistor.

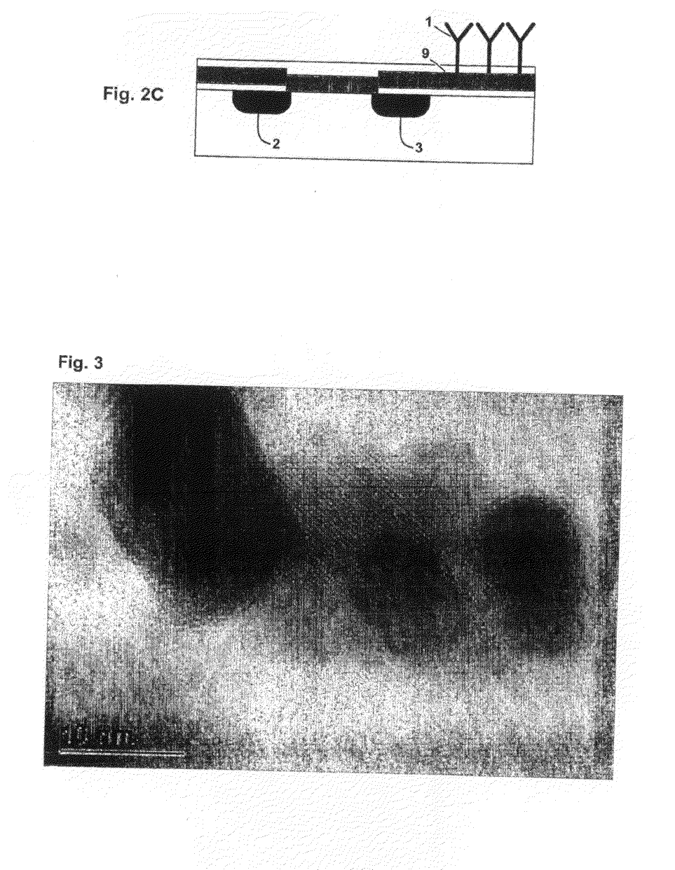

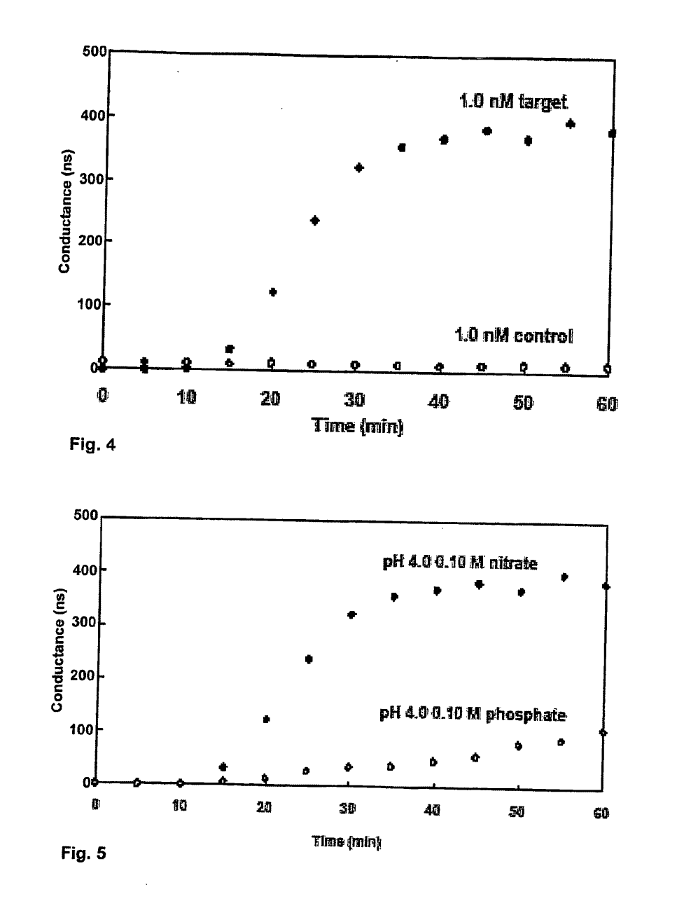

FIG. 3 depicts a photograph of activated indium tin oxide (ITO) nanoparticles, used as electroconductive nanoparticulate tags according to the method of the present invention. The photo was taken through a Transmission Electron Microscope (TEM, i.e. a TEM micrograph). FIGS. 4 to 6 are explained in the context of the following examples.

### Materials

ITO nanoparticles, butylamine, and sodium borohydride were purchased from Sigma-Aldrich (St Louis, Mo.). Saline was obtained from United Chemical Technologies (Bristol, Pa.). All other reagents of certified analytical grade were obtained from Sigma-Aldrich and used without further purification Amino-terminated peptide nucleic acid (PNA) capture probes used in this work were custom-made by Eurogentec (Herstal, Belgium) and all other oligonucleotides of PCR purity were from 1st Base Pte Ltd (Singapore). A pH 8.5 10 mM Tris-HCl-1.0 mM EDTA-0.10 M NaCl buffer solution was used as the hybridization and washing buffer. A pH 4.0 0.10 M NaNO₃ was used as the incubation buffer for direct ITO nanoparticle labeling.

### Apparatus

Electrical measurements were performed with an Advantest R8340A ultra high resistance meter (Advantest Corp., Tokyo, Japan). The biosensor consists of a pair of interlocking comblike structures (electrodes) with 150-200 fingers, each 500 nm wide and 200 mm long, and with a 500-nm gap between the two fingers of the two electrodes.

### Activation of ITO nanoparticles

The activation of the ITO nanoparticles is as follows: To 0.50 g ITO was added 50 mg ZrOCl₂ and 0.20 ml water, and the resulting slurry was mechanically grinded for 120-150 min. The mixture was suspended 5 ml ethanol and centrifuged at 12,000 rpm for 20 min. The nanoparticles were then suspended in alkalized ethanol, and it was centrifuged at 12,000 rpm for another 20 min. The nanoparticles were then washed and centrifuged with ethanol several times.

### Biosensor Preparation, Hybridization and Detection

The pretreatment and silanization of the ITO electrode were performed according to the method of Zheng et al (Nature Biotechnology (2005) 23, 1294-1301). Capture molecules of the following nucleic acid sequence were used: PNA: 3′-ACT CCA TCA TCC AAC ACA CCA A (SEQ ID NO: 1).

PNA capture probes immobilisation was carried out as follows: amine-terminated PNA capture probes were denatured for 10 min at 90° C. and diluted to a concentration of 5.0 μM in 0.10 M pH 6.0 acetate buffer. A 25 ml aliquot of the capture probes solution was dispensed onto the silanized electrode and incubated for 3-4 h at 20° C. in an environmental chamber. After incubation, the electrode was rinsed successively with 0.10% SDS and water. The unreacted aldehyde moieties were blocked by butylamine in a 1.0 mM butylamine solution in the acetate buffer. The reduction of the imines was carried out by a 5-mM incubation of the electrode in a 2.5 mg/ml sodium borohydride solution made of PBS/ethanol (3/1). The electrode was then soaked in vigorously stirred hot water (90-95° C.) for 2 min, copiously rinsed with water, and blown dry with a stream of nitrogen. The hybridization of the nucleic acid analyte molecule and its electrical detection were carried out in three steps as schematically illustrated in FIG. 1. First, the biosensor was placed in an environmental chamber maintained at 50° C. A 25 ml aliquot of hybridization solution containing the nucleic acid analyte was uniformly spread onto the biosensor. The analytes had the following nucleotide sequence: 5′-TGA GGT AGT AGG TTG TGT GGT T (SEQ ID NO: 2) and S′-UGA GGU AGU AGG UUG UGU GGU U (matched, SEQ ID NO: 3), as well as 5′-TGA GGT AGT AGG TTG TAT GGT T (one-base mismatched, SEQ ID NO: 4).

The biosensor was then rinsed thoroughly with a blank hybridization solution at 50° C. after 60 min of hybridization. ITO nanoparticles were tagged to the phosphates on the backbones of the hybridized nucleic acid analyte molecules via zirconium-phosphate chemistry after 30 min incubation at 25° C. with a 25 μl aliquot of 5-10 μg/ml ITO in 0.10 M NaNO₃ (pH 4.0, adjusted with 10 mM HNO₃). It was then thoroughly rinsed with a blank pH 4.0 0.10 M NaNO₃ solution. Electrical measurements were performed after the biosensors are completely air-dried.

### Detection Scheme

FIG. 1 shows step-by-step of the working principle of the biosensor. A monolayer of PNA capture probes was assembled in the gaps of a pair of interdigitated electrodes via saline chemistry, acting as the bioaffinitive sensing interface (A). The interaction of PNA with sample nucleic acid (B) forms a heteroduplex, bringing a high density of phosphates on the biosensor surface (C). The hybridized phosphates serve anchoring sites, providing the requisite local environment to facilitate in situ labeling, and ITO nanoparticles are the tags. As a result, at the hybridized nucleic acid molecules are tagged with multiple ITO nanoparticles (D). The formation of electrical conductive ITO nanoparticle networks in the gaps provides much needed sensitivity for the detection of nucleic acids (E). To minimize non-hybridization-related uptake of the tag and to increase the hybridization efficiency, the neutral and phosphate-free character of the PNA backbone alleviates the interaction between surface immobilised capture probe (for example oligonucleotide) and cationic tag, and the electrostatic repulsion of duplex formation, producing a high signal/noise ratio. In addition, the mismatch discrimination of PNA is in many cases much better than that of DNA offering a much higher specificity.

The ITO nanoparticles were evaluated as a novel nanoparticulate indicator for possible applications in ultrasensitive nucleic acid sensing. FIG. 4 compares the conductance changes of the biosensors after various treatments. Upon hybridization, complementary nucleic acid analyte molecules were selectively captured and bound to the biosensor and so were the ITO nanoparticles, whereas, little if any of non-complementary (control) nucleic acid was captured during hybridization. As expected, minute conductance changes were observed at the biosensor after hybridization to the control biosensor and incubation with the ITO nanoparticles (trace 1). As shown in traces 2 in FIG. 4, after hybridization with the complementary nucleic acid analyte molecules and incubation with the ITO nanoparticles, a substantial increase in conductance, by as much as 10⁴ fold, was observed which paves the way for ultrasensitive detection of nucleic acids. Extensive washing with an acidified 0.10 M NaNO₃ removed most of the non-hybridization-related ITO^{nanoparticle} uptake. These results clearly demonstrated that the ITO nanoparticles are successfully labeled the nucleic acid analyte molecule and the formation of ITO networks effectively bridge the insulating gap, generating a measurable conductance surge. Consequently, ITO nanoparticles can be used an indicator for the direct in situ labeling and ultrasensitive detection of a nucleic acid.

It was found that the composition of the labeling buffer in which the ITO nanoparticles are dispensed has a profound effect on the system. As shown in FIG. 5, the presence of phosphate in the incubation buffer significantly lifted the background conductance of the control biosensor and the sensitivity was drastically affected. This is mostly probably due to strong interaction between phosphate and the silicon oxide layer in the gap, resulting the formation of a phosphate layer in the gap, and in turn, competes with the nucleic acid analyte molecule for the ITO nanoparticles. It is therefore advantageous not to add phosphate during the process.

### Calibration Curves

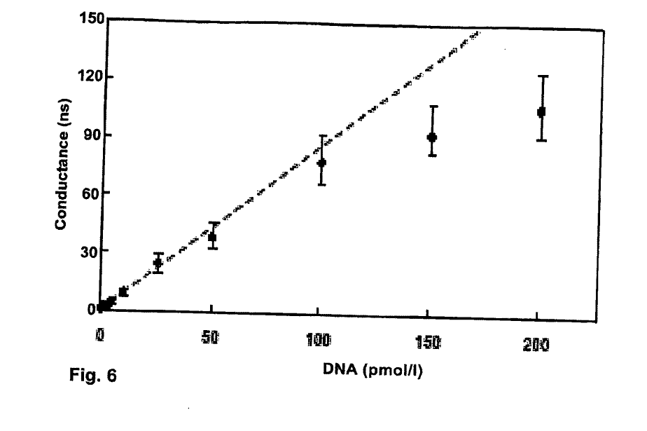

In this study, solutions of different concentrations of analyte oligonucleotides, ranging from 1.0 fM to 1.0 nM, were tested. For control measurements, non-complementary capture probes were used in the electrode preparation. As illustrated in FIG. 6, the dynamic range was from 0.20 to 100 pM, with relative standard deviations of 16-25% and a detection limit of 0.10 pM. Compared to previous nanoparticle-based nucleic acid assays, the sensitivity was greatly improved by adopting the multiple-labeling procedure. In the assays reported earlier the ratio of nanoparticle label and nucleic acid analyte molecule was fixed at unit. The amount of capture probes immobilised on the electrode surface and hybridization efficiency determine the amount of nucleic acid analyte bound to the surface and thereby the amount of nanoparticle labels. The present inventors found that it was difficult to detect traces of nucleic acid without a chemical amplification step such as silver enhancement. It may therefore be desired to select a field effect transistor for detection in such embodiments, due to their signal amplification capabilities. However, where multiple ITO nanoparticles bound to a single nucleic acid strand, a great increase in label loading occurred. As a result, the response from electrical detection proportionally increased, and hence the sensitivity and detection limit of the nucleic acid assay were substantially improved.

The use of the ITO nanoparticles as an example of electrically conductive particles has two major advantages over nanoparticles approaches so far used in the art. One is the in situ multiple labeling that alleviates the use of the second oligonucleotides. Direct in situ nanoparticle labeling is thus particularly relevant for extremely short nucleic acid analyte molecules, such as miRNAs. The other is the simplicity of the procedure, which offers great opportunity for transforming the technology to products.

### CONCLUSIONS

In summary, the above examples illustrate an electrical biosensor for the detection of biological analyte molecules based on a method of the present invention. Nucleic acids were selected as model analyte molecules. The electrical method was rapid, ultrasensitive, nonradioactive and was able to directly detect analyte molecules without involving a biological ligation or a second probe.

By employing the activated ITO nanoparticulate tags, nucleic acids were directly labeled with multiple electrically conductive ITO nanoparticles under very mild conditions. Specific nucleic acids were detected electrically at subpicomolar levels by simply measuring the conductance changes with high specificity. This electrical assay is easily extendable to a low-density array of 50-100 electrode pairs and particularly attractive for miRNAs. The relatively limited number of miRNA offers excellent opportunity for low-density electrochemical arrays in miRNA assays. The advantages of low-density electrical biosensor arrays are: (i) more cost-effective than optical biosensor arrays; (ii) ultrasensitive when coupled with catalysis; (iii) rapid, direct, turbid and light absorbing-tolerant detection and (iv) portable, robust, low-cost, and easy-to-handle electrical components suitable for field tests and homecare use. Such a tool would be of great scientific value and may open the door to routine miRNA.

The listing or discussion of a previously published document in this specification should not necessarily be taken as an acknowledgement that the document is part of the state of the art or is common general knowledge. All documents listed are hereby incorporated herein by reference in their entirety.

The invention illustratively described herein may suitably be practiced in the absence of any element or elements, limitation or limitations, not specifically disclosed herein. Thus, for example, the terms “comprising”, “including,” containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by exemplary embodiments and optional features, modification and variation of the inventions embodied therein herein disclosed may be resorted to by those skilled in the art, and that such modifications and variations are considered to be within the scope of this invention.

The invention has been described broadly and generically herein. Each of the narrower species and subgeneric groupings falling within the generic disclosure also form part of the invention. This includes the generic description of the invention with a proviso or negative limitation removing any subject matter from the genus, regardless of whether or not the excised material is specifically recited herein.

Other embodiments are within the following claims. In addition, where features or aspects of the invention are described in terms of Markush groups, those skilled in the art will recognize that the invention is also thereby described in terms of any individual member or subgroup of members of the Markush group.

What is claimed is:

1. A method of electrically detecting a biological analyte molecule by means of a pair of electrodes, wherein said electrodes are arranged at a distance from one another and wherein said pair of electrodes is arranged within a sensing zone, the method comprising:
(a) immobilising on an immobilisation unit a capture molecule, wherein the capture molecule has an affinity to the analyte molecule and is capable of forming a complex with the analyte molecule;
(b) contacting the immobilisation unit with a solution suspected to comprise the analyte molecule;
(c) allowing the analyte molecule to form a complex with the capture molecule;
(d) adding an electrically conducting nanoparticulate tag, wherein the electrically conducting nanoparticulate tag comprises or consists of electrically conducting matter that is capable of chemically interacting with the analyte molecule, thereby allowing said electrically conducting nanoparticulate tag to associate to the complex formed between said capture molecule and said analyte molecule;
(e) determining the presence of the analyte molecule based on an electrical characteristic of a region in the sensing zone, wherein the electrical characteristic is influenced by the electrically conducting nanoparticulate tag.

2. The method of claim 1, wherein (e) comprises comparing the result of d of the electrical measurement with that of a control measurement.

3. The method of claim 1 or 2, wherein the region in the sensing zone, based on the electrical characteristic of which an electrical measurement is carried out in (e), is a region in between the electrodes.

4. The method of any one of claims 1-3, wherein (a) comprises providing the immobilisation unit.

5. The method of any one of claims 1-4, wherein said biological analyte molecule is one of a nucleic acid molecule, an oligonucleotide, a protein, an oligopeptide, a polysaccharide an oligosaccharide and any composition thereof.

6. The method of any one of claims 1-5, wherein the electrical characteristic influenced by the electrically conducting nanoparticulate tag is detected by measuring any one of a conductance, a voltage, a current, a capacitance, and a resistance.

7. The method of any one of claims 1-6, wherein (f) further comprises exposing the immobilisation unit to an electric field.

8. The method of claim 7, wherein said electric field is generated at least one electrode of said pair of electrodes.

9. The method of any one of claims 1-8, wherein the sensing zone is defined by the zone in which an electric field of said pair of electrodes is effective.

10. The method of any one of claims 1-9, wherein the immobilisation unit is arranged in between the pair of electrodes.

11. The method of claim 10, wherein the immobilisation unit is arranged in a gap defined by the pair of electrodes.

12. The method of any one of claims 1-11, wherein the immobilisation unit is comprised on or conductively connected to an electrode.

13. The method of any one of claims 1-12, wherein the capture molecule is selected from the group consisting of a nucleic acid molecule, an oligonucleotide, a protein, an oligopeptide, a polysaccharide, an oligosaccharide, a synthetic polymer, a drug candidate molecule, a drug molecule, a drug metabolite, a metal ion, and a vitamin.

14. The method of claim 13, wherein the nucleic acid molecule defining the capture molecule is one of a DNA molecule, a RNA molecule and a PNA molecule.

15. The method of claim 13 or 14, wherein the nucleic acid molecule is a single-stranded capture molecule or comprises a single stranded region.

16. The method of claim 15, wherein the analyte molecule is a nucleic acid, and wherein the capture molecule has a nucleotide sequence that is at least partially complementary to at least a portion of a strand of the analyte nucleic acid molecule.

17. The method of claim 15 or 16, wherein the capture molecule has a nucleic acid sequence of a length of about 7 to about 30 bp

18. The method of claim 17, wherein the nucleic acid sequence is of a length of about 10 to about 20 bp.

19. The method of any one of claims 15-18, wherein allowing the analyte molecule to form a complex with the capture molecule comprises:
allowing the analyte molecule to hybridise to the capture molecule, the capture molecule being defined by a single-stranded nucleic acid molecule, thereby allowing the formation of a complex between the capture molecule and the analyte molecule.

20. The method of any one of claims 5-19, wherein the analyte molecule comprises a pre-defined sequence.

21. The method of any one of claims 5-20, wherein the analyte molecule is a DNA molecule or an RNA molecule.

22. The method of any one of claims 5-21, wherein the analyte molecule is a nucleic acid molecule that comprises at least one single-stranded region.

23. The method of claim 20, wherein the predefined sequence is a single-stranded region of a nucleic acid molecule.

24. The method of any one of claims 17-23, wherein the capture molecule is a single-stranded DNA molecule or a single-stranded RNA molecule, and wherein any such capture molecule that does not hybridise to an analyte molecule, is removed from the immobilisation unit.

25. The method of any one of claims 5-24, wherein the analyte molecule is or comprises an oligopeptide or a protein and said capture molecule is a receptor molecule for said polypeptide or protein and wherein said oligopeptide or protein and the receptor molecule define a specific binding pair.

26. The method of claim 25, wherein the receptor molecule is selected from the group consisting of an immunoglobulin, a mutein based on a polypeptide of the lipocalin family, a glubody, a domain antibody, a protein based on the ankyrin or crystalline scaffold, a protein based on a plurality of low-density lipoprotein receptor class A (LDLR-A) domains, an AdNectin, a tetranectin, an avimer, the T7 epitope, maltose binding protein, the HSV epitope of herpes simplex virus glycoprotein D, the hemagglutinin epitope, and the myc epitope of the transcription factor c-myc, an oligonucleotide, an oligosaccharide, an oligopeptide, biotin, dinitrophenol, digoxigenin and a metal chelator.

27. The method of claim 25 or 26, wherein the polypeptide or the protein comprises the amino acid sequence Arginine-X-X-Arginine, wherein X is any amino acid.

28. The method of any one of claims 1-27, wherein the electrically conducting nanoparticulate tag is selected from the group consisting of a nanocrystal, a nanosphere, a nanorod, a nanotube, a nanowire and a nanocup.

29. The method of claim 28, wherein adding the nanoparticulate tag comprises adding a plurality of electrically conducting nanoparticles,
thereby allowing the plurality of electrically conducting nanoparticles to associate to the complex formed between said capture molecule and said analyte molecule,
such that an electrically conducting network of said electrically conducting nanoparticles is formed, wherein the network is associated with the complex formed between the capture molecule and the analyte molecule.

30. The method of claim 29, wherein the formed electrically conducting network of said electrically conducting nanoparticles is conductively connected to the immobilisation unit.

31. The method of any one of claims 1-30, wherein the electrically conducting matter comprised in the electrically conducting nanoparticulate tag is at least one of a metal, a metalloid, carbon and a polymer.

32. The method of claim 31, wherein said metal or a metalloid comprised in the electrically conducting nanoparticulate tag is able to associate to the analyte molecule via negative charges present on the surface of the analyte molecule.

33. The method of claim 31 or 32, wherein the metalloid is a metal oxide or a metal hydroxide.

34. The method of claim 33, wherein the metalloid has an affinity to phosphate and/or phosphonate and wherein the analyte molecule is defined by a nucleic acid molecule, thereby allowing the nanoparticulate tag to associate to a nucleic acid molecule at the backbone thereof.

35. The method of claim 33 or 34, wherein the metal oxide is selected from the group consisting of indium tin oxide, titanium oxide, tantalum oxide, copper oxide and zinc oxide.

36. The method of claim 33 or 34, wherein the metal hydroxide is selected from the group consisting of aluminium hydroxide, titanium hydroxide, copper hydroxide and gold hydroxide.

37. The method of claims 31-36, wherein the metal or a metalloid is capable of forming a complex with the analyte molecule via a coordinative bond.

38. The method of claims 30-37, wherein the nanoparticulate tag further comprises a dopant and/or an activation agent.

39. The method of claim 37, wherein the coordinative bond is formed by a reaction with said activation agent.

40. The method of claim 38 or 39, wherein the activation agent is a transition metal compound or a metalloid compound.

41. The method of claim 40, wherein the transition metal compound is selected from the group consisting of a zirconium compound, a titanium compound and a niobium compound.

42. The method of claim 40, wherein the metalloid compound is a silicon compound.

43. The method of claim 41, wherein the zirconium compound is zirconyl chloride.

44. The method of claim 43, wherein the nanoparticulate tag comprises or consists of zirconyl chloride activated indium tin oxide.

45. The method of any one of claims 1-44, wherein (b) comprises immobilising a blocking agent on the immobilisation unit.

46. The method of any one of claims 1-45, wherein the analyte molecule is comprised in a sample selected from the group consisting of a soil sample, an air sample, an environmental sample, a cell culture sample, a bone marrow sample, a rainfall sample, a fallout sample, a space sample, an extraterrestrial sample, a sewage sample, a ground water sample, an abrasion sample, an archaeological sample, a food sample, a blood sample, a serum sample, a plasma sample, a urine sample, a stool sample, a semen sample, a lymphatic fluid sample, a cerebrospinal fluid sample, a naspharyngeal wash sample, a sputum sample, a mouth swab sample, a throat swab sample, a nasal swab sample, a bronchoalveolar lavage sample, a bronchial secretion sample, a milk sample, an amniotic fluid sample, a biopsy sample, a nail sample, a hair sample, a skin sample, a cancer sample, a tumour sample, a tissue sample, a cell sample, a cell lysate sample, a virus culture sample, a forensic sample, an infection sample, a nosocomial infection sample, a production sample, a drug preparation sample, a biological molecule production sample, a protein preparation sample, a lipid preparation sample, a carbohydrate preparation sample, a solution of a nucleotide, a solution of polynucleotide, a solution of a nucleic acid, a solution of a peptide, a solution of a polypeptide, a solution of an amino acid, a solution of a protein, a solution of a synthetic polymer, a solution of a biochemical composition, a solution of an organic chemical composition, a solution of an inorganic chemical composition, a solution of a lipid, a solution of a carbohydrate, a solution of a combinatory chemistry product, a solution of a drug candidate molecule, a solution of a drug molecule, a solution of a drug metabolite, a suspension of a cell, a suspension of a virus, a suspension of a microorganism, a suspension of a metal, a suspension of metal alloy, a solution of a metal ion, and any combination thereof.

47. A probe defined by an electrically conducting nanoparticulate tag, the electrically conducting nanoparticulate tag comprising or consisting of matter selected from the group consisting of a metal, a metalloid, carbon and a polymer, wherein said matter has an affinity to a biological analyte molecule and is capable of forming a complex with the analyte molecule.

48. The probe of claim 47, wherein the electrically conducting nanoparticulate tag comprises a plurality of nanoparticles of one of a nanocrystal, a nanosphere, a nanorod, a nanotube, a nanowire and a nanocup.

49. The probe of claim 47 or 48, wherein the biological analyte molecule is defined by one of a nucleic acid molecule, an oligonucleotide, a protein, an oligopeptide, a polysaccharide and an oligosaccharide.

50. The probe of any one of claims 47-49, wherein the metal or a metalloid is capable of forming a complex with the analyte molecule via negative charges present on the surface of the analyte molecule.

51. The probe of any one of claims 47-50, wherein the metalloid is a metal oxide or a metal hydroxide.

52. The probe of claim 51, wherein the metalloid has an affinity to phosphate and/or phosphonate, such that the nanoparticles associate to the backbone of a nucleic acid molecule.

53. The probe of claim 51 or 52, wherein the metal hydroxide is selected from the group consisting of aluminium hydroxide, titanium hydroxide, copper hydroxide and gold hydroxide.

54. The probe of claim 51 or 52, wherein the metal oxide is selected from the group consisting of indium tin oxide, titanium oxide, tantalum oxide, copper oxide and zinc oxide.

55. The probe of any one of claims 47-54, wherein the metal or a metalloid is capable of forming a complex with the analyte molecule via a coordinative bond.

56. The probe of any one of claims 47-55, wherein the nanoparticulate tag further comprises a dopant and/or an activation agent.

57. The probe of claim 55, wherein the coordinative bond has been obtained by a reaction with said activation agent.

58. The probe of claim 56 or 57, wherein the activation agent is a transition metal compound or a metalloid compound.

59. The probe of claim 58, wherein the metalloid compound is a silicon compound.

60. The probe of claim 58, wherein the transition metal compound is selected from the group consisting of a zirconium compound, a titanium compound and a niobium compound.

61. The probe of claim 60, wherein the zirconium compound is zirconyl chloride.

62. The probe of claim 61, wherein the nanoparticulate tag comprises or consists of zirconyl chloride activated indium tin oxide.

63. A kit for electrically detecting a biological analyte molecule, the kit comprising:
(a) a pair of electrodes, wherein said electrodes are arranged at a distance from one another and wherein said pair of electrodes is arranged within a sensing zone,
(b) an immobilisation unit arranged within said sensing zone;
(c) a capture molecule, wherein said capture molecule has an affinity to the analyte molecule and is capable of forming a complex with the analyte molecule; and
(d) an electrically conducting nanoparticulate tag, wherein the electrically conducting nanoparticulate tag comprises or consists of electrically conducting matter that is capable of chemically interacting with the analyte molecule.

64. The kit of claim 63, wherein the sensing zone is defined by the zone in which an electric field of said pair of electrodes is effective.

65. The kit of claim 63 or 64, wherein the immobilisation unit is arranged in between the pair of electrodes.

66. The kit of any one of claims 63-65, wherein the immobilisation unit is arranged in a gap defined by the pair of electrodes.

67. The kit of any one of claims 63-66, wherein the electrically conducting nanoparticulate tag comprises a plurality of nanoparticles of one of a nanocrystal, a nanosphere, a nanorod, a nanotube, a nanowire and a nanocup.

68. The kit of any one of claims 63-67, further comprising instructions for electrically detecting the biological analyte molecule.

69. The kit of any one of claims 63-68, wherein the electrically conducting matter comprised in the electrically conducting nanoparticle is at least one of a metal, a metalloid, carbon and a polymer.

70. The kit of any one of claims 63-69, wherein the capture molecule is one of a nucleic acid molecule, an oligonucleotide, a protein, an oligopeptide, a polysaccharide, an oligosaccharide, a synthetic polymer, a drug candidate molecule, a drug molecule, a drug metabolite, a metal ion, and a vitamin.


SEQUENCE LISTING (4 sequences)

SEQ ID NO: 1 - DNA, 22 bp, Artificial Sequence
  PNA capture molecule
aaccacacaacctactacctca

SEQ ID NO: 2 - DNA, 22 bp, Artificial Sequence
  analyte
tgaggtagtaggttgtgtggtt

SEQ ID NO: 3 - RNA, 22 nt, Artificial Sequence
  analyte (matched)
ugagguaguagguugugugguu

SEQ ID NO: 4 - DNA, 22 bp, Artificial Sequence
  analyte (mismatched)
tgaggtagtaggttgtatggtt